(19) United States
(12) Patent Application Publication
(10) Pub. No.: US 2026/0353768 A1
(43) Pub. Date: Nov. 5, 2026

(54) SEMICONDUCTOR DEVICE

(71) Applicant: ROHM CO., LTD., Kyoto-shi (JP)

(72) Inventor: Atsushi NOCHIDA, Kyoto-shi (JP)

(73) Assignee: ROHM CO., LTD., Kyoto-shi (JP)

(21) Appl. No.: 19/728,313

(22) Filed: Jul. 2, 2026

Related U.S. Application Data
(63) Continuation of application No. PCT/JP2024/046246, filed on Dec. 26, 2024.

(30) Foreign Application Priority Data
Jan. 11, 2024 (JP) 2024-002659

(51) Int. Cl. H10D 84/00; H10D 8/00; H10D 12/00; H10D 62/10; H10D 62/60

(52) U.S. Cl. CPC H10D 84/161; H10D 8/411; H10D 12/415; H10D 12/481; H10D 62/107; H10D 62/126; H10D 62/60

(57) ABSTRACT

A semiconductor device includes: a well region formed in a surface region of a first main surface in a peripheral region, the well region separating the peripheral region located in a peripheral edge portion of the first main surface of a chip from an IGBT region; field regions of a first conductivity type separated from the well region toward a peripheral edge of the chip, the field regions being spaced apart from each other; and a cathode region of a second conductivity type formed in a surface region of a second main surface in the peripheral region, the cathode region forming a diode together with the well region. The cathode region is located closer to the peripheral edge of the chip than the well region is, and the cathode region is formed to face at least one of the field regions in a thickness direction of the chip.

### CROSS-REFERENCE TO RELATED APPLICATIONS

This application is a continuation of, and claims the benefit of priority from International Application No. PCT/JP2024/046246, filed on Dec. 26, 2024, which claims the benefit of priority from Japanese Patent Application No. 2024-002659, filed on Jan. 11, 2024, the entire contents of each are incorporated herein by reference.

### BACKGROUND

### 1. Field

The following description relates to a semiconductor device.

### 2. Description of Related Art

JP2018-120990A discloses a semiconductor device including a reverse-conducting insulated-gate bipolar transistor (RC-IGBT).

### BRIEF DESCRIPTION OF THE DRAWINGS

FIG. 1 is a schematic plan view of a semiconductor device in accordance with a first embodiment.

FIG. 2 is a schematic plan view of a layout example under a first main surface of a chip.

FIG. 3 is a schematic plan view of a layout example of a well region, a field region, a channel stop region, and a gate wiring.

FIG. 4 is an enlarged schematic plan view of portion A outlined by single-dashed lines in FIG. 3.

FIG. 5 is a schematic cross-sectional view of the semiconductor device taken along line F5-F5 shown in FIG. 4.

FIG. 6 is a schematic cross-sectional view of the semiconductor device taken along line F6-F6 shown in FIG. 4.

FIG. 7 is a schematic cross-sectional view of the semiconductor device taken along line F7-F7 shown in FIG. 4.

FIG. 8 is a schematic cross-sectional view of the semiconductor device taken along line F8-F8 shown in FIG. 3, including a peripheral edge portion of the chip.

FIG. 9 is a graph of a first example of electric field intensity when a collector-emitter voltage is applied, relative to the position of the peripheral edge portion of the chip.

FIG. 10 is a graph of a second example of electric field intensity when a collector-emitter voltage is applied, relative to the position of the peripheral edge portion of the chip.

FIG. 11 is a graph of a third example of electric field intensity when a collector-emitter voltage is applied, relative to the position of the peripheral edge portion of the chip.

FIG. 12 is a graph of forward current relative to the position of a cathode region.

FIG. 13 is a schematic cross-sectional view of a peripheral edge portion of a chip included in a semiconductor device in accordance with a second embodiment.

FIG. 14 is a schematic cross-sectional view of the peripheral edge portion of the chip, showing a first layout example of an inner cathode region.

FIG. 15 is a graph of forward current relative to forward voltage, in accordance with various positions of the inner cathode region.

FIG. 16 is a graph of forward current relative to the position of the inner cathode region in a first setting example of a prohibition range, a first permission range, and a second permission range.

FIG. 17 is a graph of forward current relative to the position of the inner cathode region in a second setting example of the prohibition range, the first permission range, and the second permission range.

FIG. 18 is a graph of peak surge current relative to forward voltage, in accordance with various positions of the inner cathode region.

FIG. 19 is a schematic cross-sectional view of the peripheral edge portion of the chip, showing a second layout example of the inner cathode region.

FIG. 20 is a schematic cross-sectional view of the peripheral edge portion of the chip, showing a third layout example of the inner cathode region.

FIG. 21 is a schematic cross-sectional view of the peripheral edge portion of the chip included in a modified example of the semiconductor device.

FIG. 22 is a schematic cross-sectional view of the peripheral edge portion of the chip included in a modified example of the semiconductor device.

FIG. 23 is a schematic cross-sectional view of the peripheral edge portion of the chip included in a modified example of the semiconductor device.

FIG. 24 is a schematic cross-sectional view of the peripheral edge portion of the chip included in a modified example of the semiconductor device.

FIG. 25 is a schematic cross-sectional view of the peripheral edge portion of the chip included in a modified example of the semiconductor device.

FIG. 26 is a schematic cross-sectional view of the peripheral edge portion of the chip included in a modified example of the semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a semiconductor device according to the present disclosure will now be described with reference to the accompanying drawings. Elements in the drawings may not be drawn to scale for simplicity and clarity of illustration. In the cross-sectional drawings, hatching lines may not be shown to facilitate understanding. The accompanying drawings merely illustrate exemplary embodiments of the present disclosure and are not intended to limit the present disclosure.

This detailed description includes exemplary embodiments of devices, systems, and methods in accordance with the present disclosure. The present description is illustrative and is not intended to limit the embodiments of the present disclosure or application and use of the embodiments.

In this specification, the phrase “at least one of” as used in this disclosure means “one or more” of desired options. In an example, the phrase “at least one of” means “only one of two options” or “both of two options” if the number of options is two. In another example, the phrase “at least one of” means “only one of the options” or “any combination of two or more of the options” if the number of options is three or more.

In this specification, phrases such as “the dimension (depth, width, length, height) of A is equal to the dimension (depth, width, length, height) of B” or “A and B have the same dimension (depth, width, length, height)” include a relationship in which a difference between the dimension (depth, width, length, height) of A and the dimension (depth, width, length, height) of B is, for example, within 10% of the dimension (depth, width, length, height) of A. In this specification, phrases such as “the concentration of A is equal to the concentration of B” or “A and B have the same concentration” include a relationship in which a difference between the concentration of A and the concentration of B is, for example, within 10% of the concentration of A.

### First Embodiment

### Overall Configuration of Semiconductor Device

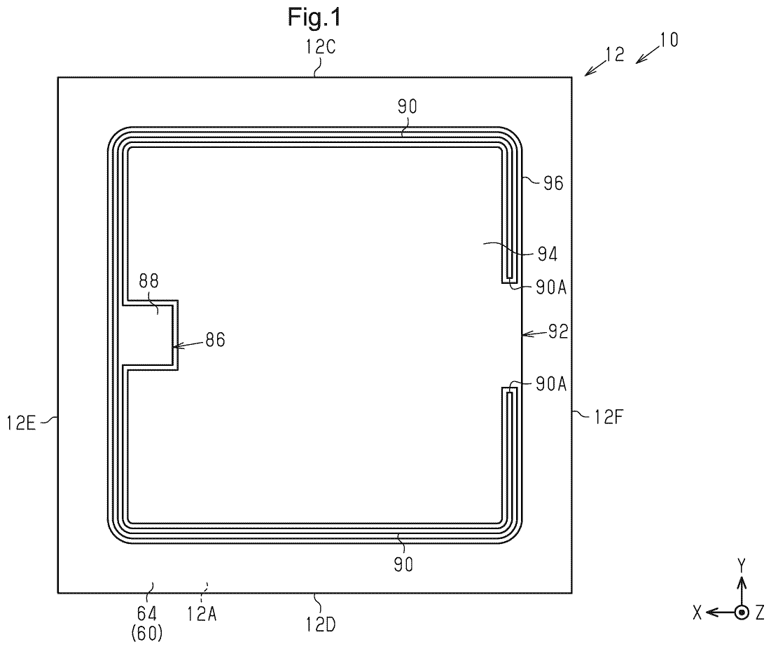

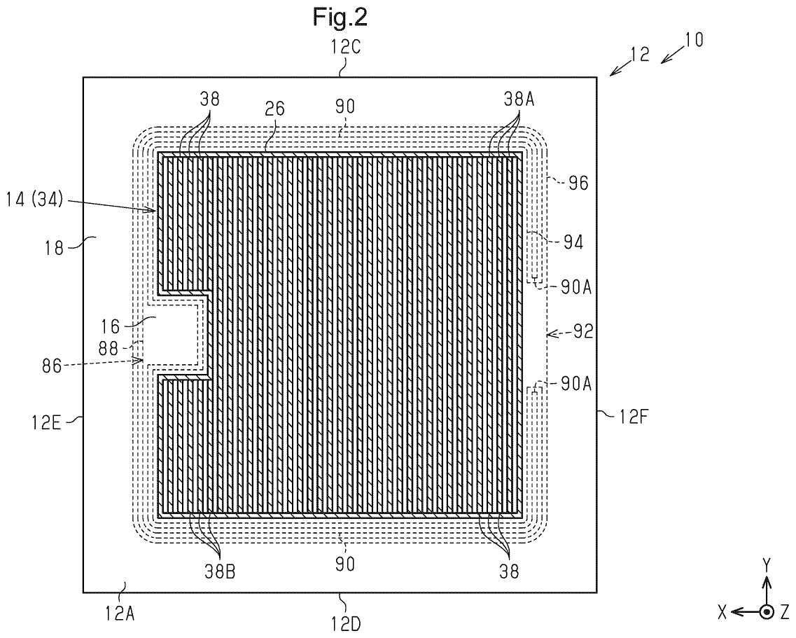

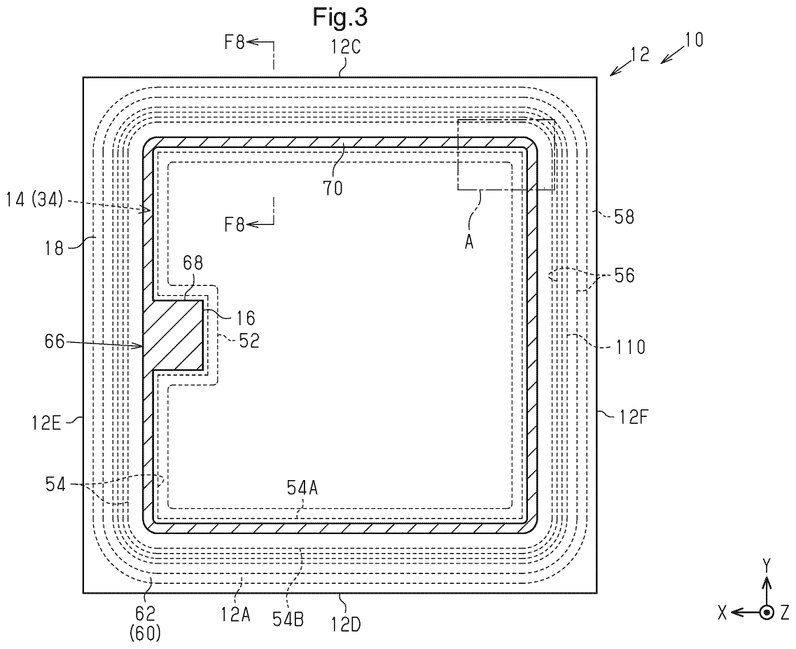

An overall configuration of a semiconductor device 10 in accordance with a first embodiment will now be described with reference to FIGS. 1 to 8. FIG. 1 is a schematic plan view of the semiconductor device 10 in accordance with the first embodiment. FIG. 2 is a schematic diagram of a layout example of various wiring in the semiconductor device 10 shown in FIG. 1. FIG. 3 is a schematic diagram of a layout example of a well region 54, field regions 56, a gate line wiring 70, and a cathode region 110, which will be described later. FIG. 2 does not show a field electrode 102 and a channel stop electrode 106, which will be described later. FIG. 3 shows the field regions 56 as a single region to simplify illustration.

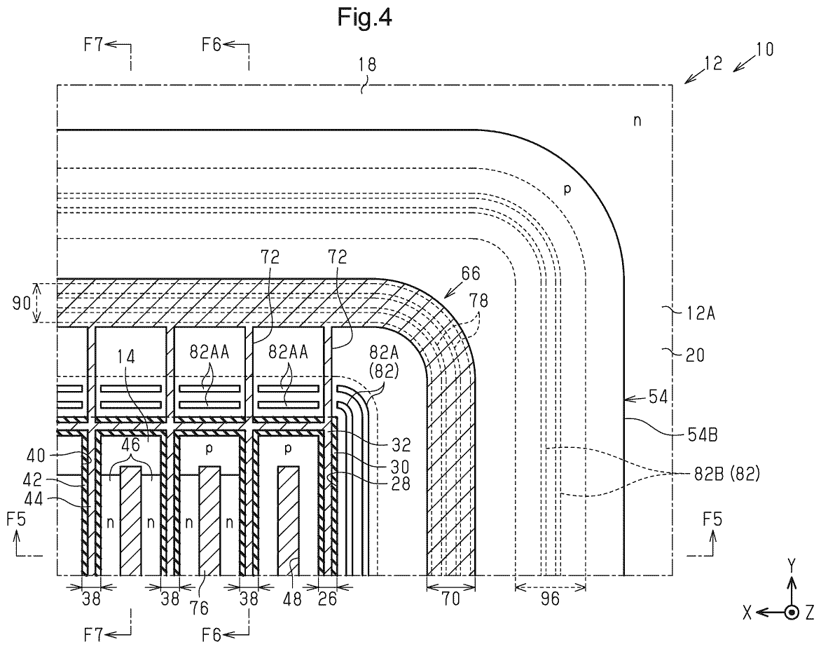

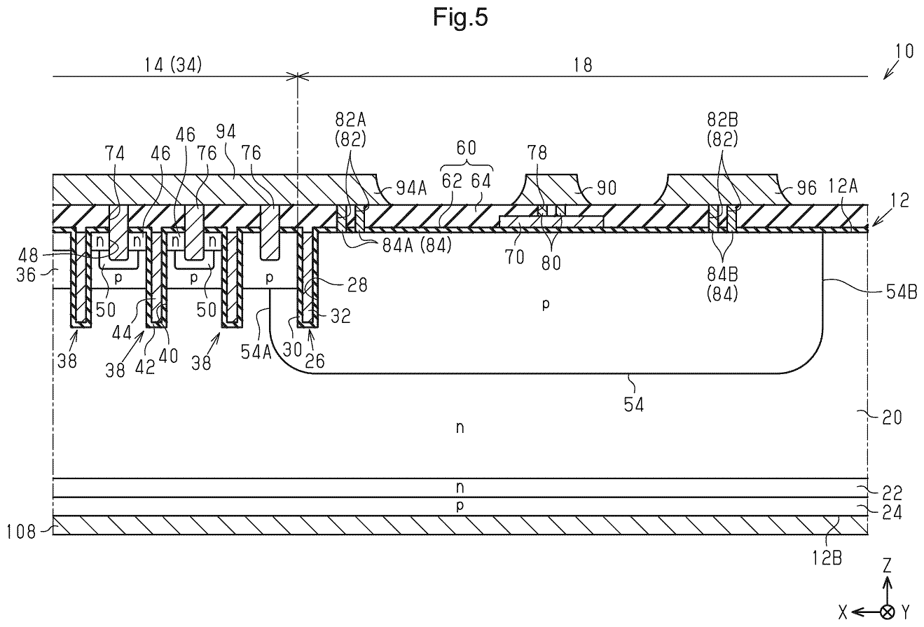

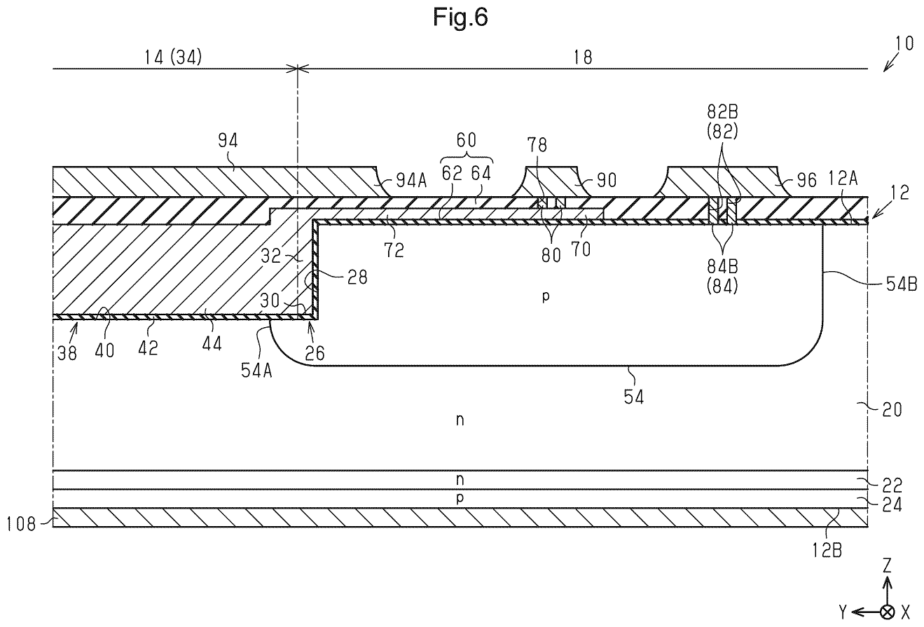

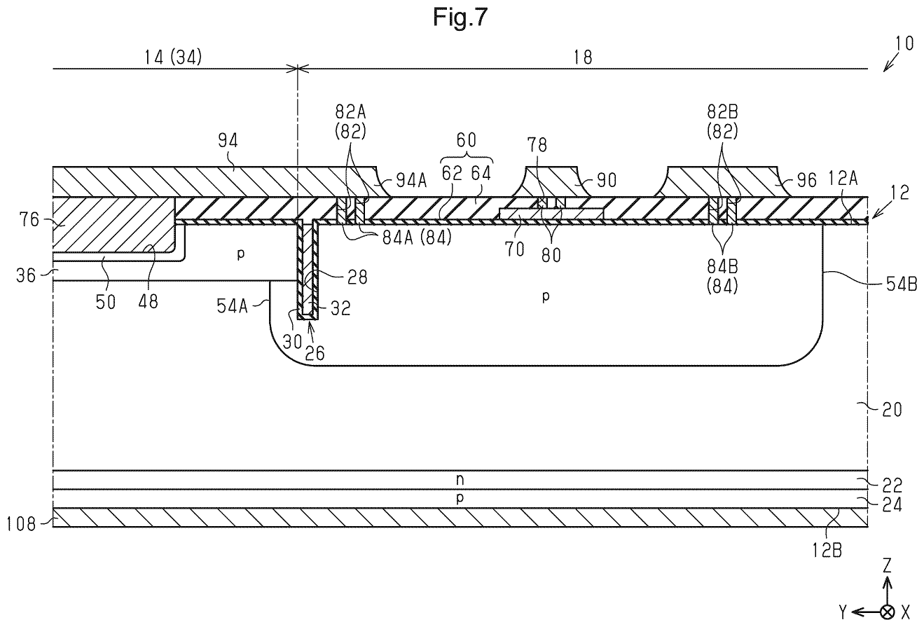

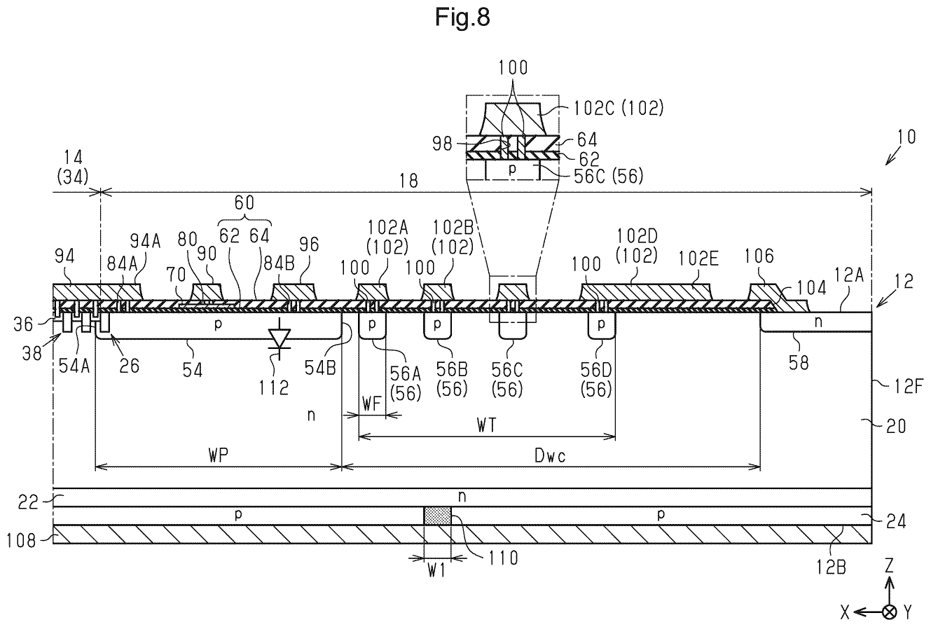

FIG. 4 is a plan view of part of the chip 12. FIG. 5 is a schematic cross-sectional view of the semiconductor device taken along line F5-F5 shown in FIG. 4. FIG. 6 is a schematic cross-sectional view of the semiconductor device taken along line F6-F6 shown in FIG. 4. FIG. 7 is a schematic cross-sectional view of the semiconductor device taken along line F7-F7 shown in FIG. 4. FIG. 8 is a schematic cross-sectional view of a peripheral edge portion of the chip 12, which will be described later.

As shown in FIGS. 1 to 3, the semiconductor device 10 is an RC-IGBT semiconductor device including a reverse-conducting insulated-gate bipolar transistor (RC-IGBT), which incorporates an insulated-gate bipolar transistor (IGBT) and a diode. The diode is a freewheeling diode for the IGBT. Such an RC-IGBT semiconductor device may be referred to as a “semiconductor switching device.”

As shown in FIG. 1, the semiconductor device 10 includes a six-sided chip 12. In other words, the chip 12 has a flat plate shape and has a thickness in a Z-direction. The chip 12 may be referred to as a “semiconductor chip.” In the first embodiment, the chip 12 has a single-layer structure formed by a silicon single crystal substrate (semiconductor substrate). The chip 12 includes a first main surface 12A, a second main surface 12B opposite of the first main surface 12A (refer to FIG. 5), and first to fourth side surfaces 12C to 12F connecting the first main surface 12A and the second main surface 12B. Hereinafter, a view of the semiconductor device 10 in the Z-direction will be referred to as a “plan view.” Further, directions orthogonal to the Z-direction will be referred to as the X-direction and the Y-direction, which are orthogonal to each other.

The first main surface 12A and the second main surface 12B are both quadrangular in plan view. The first side surface 12C and the second side surface 12D define two opposite end surfaces of the chip 12 in the Y-direction. The first side surface 12C and the second side surface 12D both extend in the X-direction in plan view. The third side surface 12E and the fourth side surface 12F define two opposite end surfaces of the chip 12 in the X-direction. The third side surface 12E and the fourth side surface 12F both extend in the Y-direction in plan view.

As shown in FIG. 2, the semiconductor device 10 includes an IGBT region 14 located in an inner part of the first main surface 12A. The IGBT region 14 is a region that includes an IGBT structure, and may be referred to as an “active region.” In an example, the IGBT region 14 has a polygonal shape with four sides respectively parallel to the first to fourth side surfaces 12C to 12F in plan view. In the example shown in FIG. 2, in plan view, the IGBT region 14 includes a recess recessed from a central part of a side extending along the third side surface 12E in the Y-direction. The recess is recessed toward the fourth side surface 12F. The recess has a polygonal shape in plan view. In the example shown in FIG. 2, the recess has a quadrangular shape in plan view.

The semiconductor device 10 includes a pad region 16 and a peripheral region 18. The pad region 16 is a region of the first main surface 12A defined by the recess of the IGBT region 14. The peripheral region 18 is located in a peripheral edge portion of the chip 12. The pad region 16 has a polygonal shape in plan view. In the example shown in FIG. 2, the pad region 16 has a quadrilateral shape in plan view. The peripheral region 18 has a loop shape extending along the first to fourth side surfaces 12C to 12F to surround the IGBT region 14 in plan view. In the example shown in FIG. 2, the peripheral region 18 has a quadrangular loop shape in plan view. A portion of the peripheral region 18 extending along the third side surface 12E is connected to the pad region 16. In other words, the IGBT region 14 is located at an inner side of the peripheral region 18 of the first main surface 12A.

As shown in FIG. 5, the semiconductor device 10 includes an n-type (second conductivity type) drift region 20 formed inside the chip 12. The drift region 20 extends across the internal region of the chip 12. In the first embodiment, the chip 12 is formed by an n-type semiconductor substrate (n-type semiconductor chip). The drift region 20 is formed using the chip 12.

The semiconductor device 10 includes an n-type buffer region 22 formed in a surface region of the second main surface 12B. In the first embodiment, the buffer region 22 forms a layer that extends across the entire second main surface 12B. The buffer region 22 is exposed in the first to fourth side surfaces 12C to 12F (refer to FIG. 2). The buffer region 22 has a higher n-type impurity concentration than the drift region 20. The buffer region 22 may be omitted.

The semiconductor device 10 includes a p-type (first conductivity type) collector region 24 formed in a surface region of the second main surface 12B. The collector region 24 is formed in a surface portion of the buffer region 22 located at a side relatively close to the second main surface 12B. In the first embodiment, the collector region 24 forms a layer that extends across substantially the entire second main surface 12B.

The semiconductor device 10 includes a trench isolation structure 26 formed in the first main surface 12A to define the IGBT region 14. The trench isolation structure 26 receives a gate potential. The trench isolation structure 26 surrounds the IGBT region 14 and isolates the IGBT region 14 from the peripheral region 18 and the pad region 16 (refer to FIG. 2). In the first embodiment, the trench isolation structure 26 has a polygonal loop shape with four sides respectively parallel to the first to fourth side surfaces 12C to 12F in plan view.

The trench isolation structure 26 may have a width in a range of 0.5 μm to 5 μm, inclusive. The width of the trench isolation structure 26 may be defined by a dimension orthogonal to the direction in which the trench isolation structure 26 extends in plan view. Preferably, the width of the trench isolation structure 26 is in a range of 1 μm to 2.5 μm, inclusive. The trench isolation structure 26 may have a depth in a range of 1 μm to 20 μm, inclusive. The depth of the trench isolation structure 26 may be defined by a dimension of the trench isolation structure 26 in the Z-direction; specifically, a distance from the first main surface 12A to a bottom wall of an isolation trench 28 (described later) in the Z-direction. Preferably, the depth of the trench isolation structure 26 is in a range of 4 μm to 10 μm, inclusive.

The trench isolation structure 26 includes the isolation trench 28, an isolation insulating film 30, and an isolation embedded electrode 32. The isolation trench 28 is formed by digging the first main surface 12A toward the second main surface 12B, and defines the wall surfaces of the trench isolation structure 26. The isolation insulating film 30 extends along the wall surfaces of the isolation trench 28. The isolation insulating film 30 defines the recessed area of the isolation trench 28.

The isolation insulating film 30 may include at least one of a silicon oxide film, a silicon nitride film, a silicon oxynitride film, and an aluminum oxide film. Preferably, the isolation insulating film 30 has a single-layer structure formed by a single insulating film. It is particularly preferred that the isolation insulating film 30 includes a silicon oxide film formed of an oxide of the chip 12.

The isolation embedded electrode 32 is embedded in the isolation trench 28 with the isolation insulating film 30 located in between. In the first embodiment, the isolation embedded electrode 32 is formed of a conductive polysilicon. The isolation embedded electrode 32 receives a gate potential.

The semiconductor device 10 includes an IGBT structure 34 formed in the IGBT region 14. The IGBT structure 34 may be referred to as a “field-effect transistor (FET) structure.” The IGBT structure 34 includes a p-type base region 36 formed in a surface region of the first main surface 12A in the IGBT region 14. The base region 36 may be referred to as a “body region” or a “channel region.” The base region 36 is shallower than the trench isolation structure 26. In other words, the base region 36 has a bottom located closer to the first main surface 12A than the bottom wall of the trench isolation structure 26 is. The base region 36 forms a layer that extends along the first main surface 12A. The base region 36 is in contact with an inner peripheral wall of the trench isolation structure 26.

The IGBT structure 34 includes trench gate structures 38 formed in the first main surface 12A in the IGBT region 14. The trench gate structures 38 receive a gate potential. The trench gate structures 38 extend through the base region 36 into the drift region 20. As shown in FIG. 2, the trench gate structures 38 are arranged at intervals in the X-direction in plan view. Each of the trench gate structures 38 has a strip shape that extends in the Y-direction in plan view. Accordingly, the trench gate structures 38 are arranged in a striped pattern that extends in the Y-direction.

The trench gate structures 38 each include a first end 38A located at one side (relatively close to the first side surface 12C) and a second end 38B located at the other side (relatively close to the second side surface 12D) in a longitudinal direction (Y-direction). The first end 38A and the second end 38B are mechanically and electrically connected to the trench isolation structure 26.

Accordingly, the trench gate structures 38 form a single ladder-shaped trench gate structure 38 together with the trench isolation structure 26. A portion in which the trench isolation structure 26 is connected to the trench gate structure 38 may be considered as either part of the trench isolation structure 26 or part of the trench gate structure 38.

The trench gate structures 38 may be arranged at intervals of 0.5 μm to 5 μm, inclusive, in the X-direction. Preferably, the interval of the trench gate structures 38 is in a range of 1 μm to 3 μm, inclusive. The trench gate structures 38 may each have a width in a range of 0.5 μm to 5 μm, inclusive. The width of the trench gate structure 38 may be defined by a dimension orthogonal to the direction in which the trench gate structure 38 extends in plan view.

Preferably, the width of each trench gate structure 38 is in a range of 1 μm to 2.5 μm, inclusive. Preferably, the width of each trench gate structure 38 is equal to the width of the trench isolation structure 26. Each trench gate structure 38 may have a depth in a range of 1 μm to 20 μm, inclusive. The depth of the trench gate structure 38 may be defined by a dimension of the trench gate structure 38 in the Z-direction. Preferably, the depth of the trench gate structure 38 is in a range of 4 μm to 10 μm, inclusive. Preferably, the depth of the trench gate structure 38 is equal to the depth of the trench isolation structure 26. The depth of the trench gate structure 38 may be defined by a dimension of the trench gate structure 38 in the Z-direction; specifically, a distance from the first main surface 12A to a bottom wall of a gate trench 40 (described later) in the Z-direction.

One of the trench gate structures 38 will now be described.

As shown in FIG. 5, the trench gate structure 38 includes the gate trench 40, a gate insulating film 42, and a gate embedded electrode 44. The gate trench 40 is formed by digging the first main surface 12A toward the second main surface 12B, and defines the wall surfaces of the trench gate structure 38. In the first embodiment, the gate trench 40 includes two longitudinal ends, namely, the first end 38A and the second end 38B (refer to FIG. 2), and is continuous with the isolation trench 28 at these two longitudinal ends. More specifically, as shown in FIG. 4, the side walls of the gate trench 40 are continuous with the side walls of the isolation trench 28, and the bottom wall of the gate trench 40 is continuous with the bottom wall of the isolation trench 28.

As shown in FIGS. 4 and 5, the gate insulating film 42 extends along the wall surfaces of the gate trench 40. The gate insulating film 42 defines a recessed area of the gate trench 40. The gate insulating film 42 may include at least one of a silicon oxide film, a silicon nitride film, a silicon oxynitride film, and an aluminum oxide film. Preferably, the gate insulating film 42 has a single-layer structure formed by a single insulating film. It is particularly preferred that the gate insulating film 42 includes a silicon oxide film formed of an oxide of the chip 12. In the first embodiment, the gate insulating film 42 is formed by the same insulating film as the isolation insulating film 30. The gate insulating film 42 is connected to the isolation insulating film 30 at a portion in which the isolation trench 28 is continuous with the gate trench 40.

The gate embedded electrode 44 is embedded in the gate trench 40 with the gate insulating film 42 located in between. In the first embodiment, the gate embedded electrode 44 is formed of conductive polysilicon. The gate embedded electrode 44 receives a gate potential. The gate embedded electrode 44 is connected to the isolation embedded electrode 32 at a portion in which the isolation trench 28 is continuous with the gate trench 40.

As shown in FIG. 5, the IGBT structure 34 includes n-type emitter regions 46 formed in a surface portion of the base region 36 in regions extending along the trench gate structures 38. The emitter regions 46 are located at opposite sides of each of the trench gate structures 38. The emitter regions 46 each have a strip shape that extends along the trench gate structures 38 in plan view. The emitter regions 46 each have a higher n-type impurity concentration than the drift region 20. Preferably, the emitter regions 46 are not formed in a region sandwiched between the trench isolation structure 26 and the trench gate structure 38 in the surface portion of the base region 36.

The IGBT structure 34 includes contact holes 48 formed in the first main surface 12A to expose the emitter regions 46. The contact holes 48 are each formed in a region between two adjacent ones of the trench gate structures 38, which are separated from each other. In the first embodiment, the contact holes 48 each have an opening width that is constant from the opening end to the bottom wall. The contact holes 48 may each be tapered such that the opening width decreases from the opening end toward the bottom wall.

In the first embodiment, the contact holes 48 extend through the emitter regions 46 into the base region 36. The contact holes 48 do not have to extend into the base region 36, and may be spaced apart from the bottom of the emitter regions 46 toward the first main surface 12A. The contact holes 48 each have a strip shape that extends along the trench gate structures 38 in plan view. As shown in FIG. 7, the contact holes 48 are spaced apart from the trench isolation structure 26 in the longitudinal direction (the Y-direction). Accordingly, the contact holes 48 are shorter than the trench gate structures 38 (refer to FIG. 6) in the longitudinal direction (Y-direction).

As shown in FIG. 5, the IGBT structure 34 includes p-type contact regions 50 formed in a surface portion of the base region 36. The contact regions 50 and the emitter regions 46 are formed in different regions of the surface portion of the base region 36. The contact regions 50 each have a strip shape that extends along a corresponding one of the contact holes 48 in plan view. The contact regions 50 each have a bottom located in a region between the bottom wall of the corresponding one of the contact holes 48 and the bottom of the base region 36. The contact regions 50 each have a higher p-type impurity concentration than the base region 36.

As shown in FIG. 3, the semiconductor device 10 includes a p-type pad well region 52 formed in a surface region of the first main surface 12A in the pad region 16. The pad well region 52 is formed to define the IGBT region 14. The pad well region 52 may be referred to as a “pad anode region.” In the first embodiment, the pad well region 52 has a higher p-type impurity concentration than the base region 36 (refer to FIG. 5). The pad well region 52 may have a lower p-type impurity concentration than the base region 36.

The pad well region 52 formed in the pad region 16 is separated from a peripheral edge of the chip 12 toward the IGBT region 14. The pad well region 52 has a polygonal shape (in the first embodiment, a quadrangular shape) that matches the pad region 16 in plan view. The pad well region 52 is in contact with the trench isolation structure 26 (refer to FIG. 2). The pad well region 52 is deeper than the base region 36. Specifically, the pad well region 52 is deeper than the trench isolation structure 26 (trench gate structures 38). The pad well region 52 includes a portion that covers the bottom wall of the trench isolation structure 26.

The pad well region 52 includes a peripheral edge portion extending out of the pad region 16 into the IGBT region 14. The peripheral edge portion of the pad well region 52 includes a portion that extends beyond the trench isolation structure 26 to cover the bottom walls of the trench gate structures 38. The peripheral edge portion of the pad well region 52 covers the side walls of the trench isolation structure 26 and the side walls of the trench gate structures 38 in the IGBT region 14, and is connected to the base region 36 in a surface region of the first main surface 12A. In other words, the pad well region 52 is electrically connected to the base region 36 and the emitter regions 46 in the IGBT region 14.

As shown in FIGS. 5 to 8, the semiconductor device 10 includes a p-type well region 54 formed in a surface region of the first main surface 12A in the peripheral region 18. The well region 54 separates the IGBT region 14 from the peripheral region 18. The well region 54 may be referred to as an “anode region.” In the first embodiment, the well region 54 has a higher p-type impurity concentration than the base region 36. The well region 54 may have a lower p-type impurity concentration than the base region 36. Preferably, the well region 54 has a p-type impurity concentration equal to that of the pad well region 52.

The well region 54 is separated from the peripheral edge of the chip 12 toward the IGBT region 14. The well region 54 forms a layer that extends along the first main surface 12A. The well region 54 is exposed from the first main surface 12A. The well region 54 has a strip shape that extends along the IGBT region 14 in plan view. Specifically, as shown in FIG. 3, the well region 54 has a loop shape that surrounds the IGBT region 14 in plan view. The well region 54 has four sides respectively parallel to the peripheral edges of the chip 12. The well region 54 includes an inner edge 54A located relatively close to the IGBT region 14, and an outer edge 54B located relatively close to the peripheral edge of the chip 12.

A portion of the well region 54 extending along the third side surface 12E is formed integrally with the pad well region 52. In other words, the well region 54 integrally includes the pad well region 52, which extends from a side relatively close to the peripheral region 18 into the pad region 16. The well region 54 may have a width in a range of 10 μm to 100 μm, inclusive. Preferably, the width of the well region 54 is in a range of 40 μm to 80 μm, inclusive. The width of the well region 54 may be defined by a dimension orthogonal to the direction in which the well region 54 extends in plan view.

As shown in FIG. 5, the well region 54 is deeper than the base region 36. Specifically, the well region 54 is deeper than the trench isolation structure 26 (trench gate structures 38). The well region 54 is in contact with the trench isolation structure 26. The well region 54 includes a portion that covers the bottom wall of the trench isolation structure 26. The well region 54 extends from the peripheral region 18 into the IGBT region 14. Accordingly, the inner edge 54A of the well region 54 is located in the IGBT region 14.

As shown in FIGS. 6 and 7, the well region 54 includes a portion that extends beyond the trench isolation structure 26 and covers the bottom walls of the trench gate structures 38. The well region 54 covers the side walls of the trench isolation structure 26 and the side walls of the trench gate structures 38 in the IGBT region 14, and is connected to the base region 36 in a surface region of the first main surface 12A. In other words, as shown in FIGS. 5 and 7, the inner edge 54A of the well region 54 is electrically connected to the base region 36 and the emitter regions 46 in the IGBT region 14.

As shown in FIG. 8, the semiconductor device 10 includes at least one p-type field region 56 formed in a surface region of the first main surface 12A in the peripheral region 18. In an example, multiple (in the first embodiment, four) field regions 56 are formed. The number of field regions 56 may be changed. For example, the number of field regions 56 may be between one and twenty, inclusive (typically, between three and ten, inclusive). The field regions 56 may each have a higher p-type impurity concentration than the base region 36. The field regions 56 may each have a p-type impurity concentration equal to that of the well region 54. The field regions 56 are electrically floating.

The field regions 56 are formed between the well region 54 and the peripheral edge of the chip 12, and are separated from both the well region 54 and the peripheral edge of the chip 12. The field regions 56 each have a strip shape that extends along the well region 54 in plan view. In an example, as shown in FIG. 3, the field regions 56 each have a loop shape (in the first embodiment, a quadrangular loop) that surrounds the well region 54 in plan view.

As shown in FIG. 8, the field regions 56 include an outermost field region 56D and inner field regions 56A to 56C. The outermost field region 56D is located closest to the peripheral edge of the chip 12. The inner field regions 56A to 56C are located closer to the well region 54 than the outermost field region 56D is. Hereinafter, the outermost field region 56D and the inner field regions 56A to 56C may each be simply referred to as “the field regions 56” without distinguishing one from the other.

Preferably, the field regions 56 are deeper than the base region 36. Preferably, the field regions 56 are shallower than the well region 54. Preferably, the field regions 56 are shallower than the bottom position of the well region 54 by, for example, 0.1 μm or greater and 1 μm or less (preferably, 0.5 μm or less).

Preferably, the field regions 56 have the same depth. Preferably, the distance between two adjacent ones of the field regions 56 in a width direction of the field regions 56 (hereinafter, “the spacing of the field regions 56”) is set to gradually increase toward the peripheral edge of the chip 12. The spacing of the field regions 56 may be constant.

Preferably, the field regions 56 each have a smaller width than the well region 54. The inner field regions 56A to 56C have the same width. The width of the outermost field region 56D is equal to that of the inner field regions 56A to 56C. Hereinafter, the width of the inner field regions 56A to 56C and the width of the outermost field region 56D may each be simply referred to as “the width WF of the field region 56” without distinguishing one from the other. The width WF of the field region 56 (width of inner field regions 56A to 56C or width of outermost field region 56D) may be defined by a dimension orthogonal to the direction in which the field region 56 extends in plan view.

The width WF of the field region 56 may be in a range of 1 μm to 50 μm, inclusive. The width WF of the field region 56 may be set to a value included in any one of a range of 1 μm to 2.5 μm, inclusive, a range of 2.5 μm to 5 μm, inclusive, a range of 5 μm to 7.5 μm, inclusive, a range of 7.5 μm to 10 μm, inclusive, a range of 10 μm to 20 μm, inclusive, a range of 20 μm to 30 μm, inclusive, a range of 30 μm to 40 μm, inclusive, and a range of 40 μm to 50 μm, inclusive. Preferably, the width WF of the field region 56 is in a range of 10 μm to 30 μm, inclusive.

The spacing of the field regions 56 may be in a range from 10 μm to 30 μm, inclusive. The spacing of the field regions 56 may be in a range from 10 μm to 20 μm, inclusive. The spacing of the field regions 56 may be in a range from 10 μm to 15 μm, inclusive.

The semiconductor device 10 includes an n-type channel stop region 58 formed in a surface region of the first main surface 12A in the peripheral region 18. The channel stop region 58 is separated from the field regions 56 toward the peripheral edge of the chip 12. The channel stop region 58 has a higher n-type impurity concentration than the drift region 20. The channel stop region 58 may be exposed from the first to fourth side surfaces 12C to 12F (refer to FIG. 3).

As shown in FIG. 3, the channel stop region 58 has a strip shape that extends along the peripheral edge of the chip 12 in plan view. In an example, the channel stop region 58 has a loop shape (in the first embodiment, a quadrangular loop) that surrounds the field regions 56 in plan view. The channel stop region 58 is electrically floating.

As shown in FIGS. 5 to 8, the semiconductor device 10 includes an insulating film 60 that selectively covers the first main surface 12A. In the first embodiment, the insulating film 60 has a multi-layer structure including a main-surface insulating film 62 and an interlayer insulating film 64. The main-surface insulating film 62 selectively covers the first main surface 12A in the IGBT region 14, the peripheral region 18, and the pad region 16 (refer to FIG. 3). The main-surface insulating film 62 may include at least one of a silicon oxide film, a silicon nitride film, a silicon oxynitride film, and an aluminum oxide film. Preferably, the main-surface insulating film 62 has a single-layer structure formed by a single insulating film.

It is particularly preferred that the main-surface insulating film 62 includes a silicon oxide film formed of an oxide of the chip 12. In an example, as shown in FIGS. 5 and 6, the main-surface insulating film 62 is formed by the same insulating film as the gate insulating film 42. The main-surface insulating film 62 covers the first main surface 12A so as to expose the trench isolation structure 26 and the trench gate structures 38.

Specifically, the main-surface insulating film 62 is connected to the isolation insulating film 30 and the gate insulating film 42. Further, the main-surface insulating film 62 exposes the isolation embedded electrode 32 and the gate embedded electrodes 44. The main-surface insulating film 62 covers the pad well region 52 (refer to FIG. 3), the well region 54, the field regions 56, and the channel stop region 58 in the pad region 16 and the peripheral region 18.

The interlayer insulating film 64 covers the main-surface insulating film 62. The interlayer insulating film 64 is thicker than the main-surface insulating film 62. The interlayer insulating film 64 may have a single-layer structure formed by a single insulating film or a multi-layer structure formed by multiple insulating films. The interlayer insulating film 64 may include at least one of a silicon oxide film, a silicon nitride film, a silicon oxynitride film, and an aluminum oxide film. The interlayer insulating film 64 may include at least one of the following examples of a silicon oxide film: a non-doped silicate glass (NSG) film, a phosphor silicate glass (PSG) film, and a boron phosphor silicate glass (BPSG) film.

The interlayer insulating film 64 covers the main-surface insulating film 62 in the IGBT region 14, the peripheral region 18, and the pad region 16. The interlayer insulating film 64 covers the main-surface insulating film 62, the trench isolation structure 26, and the trench gate structures 38 in the IGBT region 14. As shown in FIG. 8, the interlayer insulating film 64 covers the pad well region 52, the well region 54, the field regions 56, and the channel stop region 58 in the pad region 16 (refer to FIG. 3) and the peripheral region 18, with the main-surface insulating film 62 located in between.

As shown in FIG. 3, the semiconductor device 10 includes a gate wiring 66 that forms a film located inside the insulating film 60. In the first embodiment, the gate wiring 66 is formed by a conductive polysilicon film. In an example, as shown in FIGS. 3 and 6, the gate wiring 66 includes a gate pad wiring 68, a gate line wiring 70, and gate connection wirings 72. The gate line wiring 70 may be referred to as a “gate finger wiring.”

As shown in FIG. 3, the gate pad wiring 68 is located inside a portion of the insulating film 60 that covers the pad region 16. The gate pad wiring 68 faces the pad well region 52 in the thickness direction (Z-direction) of the chip 12. Specifically, the gate pad wiring 68 forms a film located on the main-surface insulating film 62 and is covered by the interlayer insulating film 64 (refer to FIG. 6). The gate pad wiring 68 has a polygonal shape (in the first embodiment, a quadrangular shape) that matches the pad region 16 in plan view. The gate pad wiring 68 may include a peripheral edge portion located inside the pad region 16.

The peripheral edge portion of the gate pad wiring 68 may extend from the pad region 16 toward the IGBT region 14. In this case, the peripheral edge portion of the gate pad wiring 68 located on the main-surface insulating film 62 may extend onto a portion of the trench isolation structure 26 (refer to FIG. 6) defining the pad region 16, and may be connected to the isolation embedded electrode 32 (refer to FIG. 6). Further, the peripheral edge portion of the gate pad wiring 68 may cover parts (first end 38A and second end 38B, refer to FIG. 2) of the trench gate structures 38 and may be connected to the gate embedded electrodes 44 (refer to FIG. 6).

The gate line wiring 70 is located inside a portion of the insulating film 60 that covers the peripheral region 18. As shown in FIGS. 5 to 7, the gate line wiring 70 faces the well region 54 in the thickness direction (Z-direction) of the chip 12. Specifically, the gate line wiring 70 forms a film located on the main-surface insulating film 62 and is covered by the interlayer insulating film 64. In the first embodiment, the gate line wiring 70 is formed only in a portion of the insulating film 60 that covers the well region 54. In other words, in plan view, the gate line wiring 70 is separated from both the outer edge 54B and the inner edge 54A of the well region 54, and faces an inner part of the well region 54. Further, the entire gate line wiring 70 faces the well region 54 with the main-surface insulating film 62 located in between.

As shown in FIG. 3, the gate line wiring 70 has a strip shape that extends along the well region 54 in plan view. Preferably, the gate line wiring 70 defines the IGBT region 14 from multiple directions in plan view. In the first embodiment, the gate line wiring 70 has a strip shape that extends along the first to fourth side surfaces 12C to 12F in plan view. The gate line wiring 70 defines the IGBT region 14 from four directions. The gate line wiring 70 may have an endless or open-ended strip shape that surrounds the IGBT region 14. In an example, the gate line wiring 70 has a loop shape (in the first embodiment, a quadrangular loop) that surrounds the IGBT region 14.

A portion of the gate line wiring 70 extending along the third side surface 12E is formed integrally with the gate pad wiring 68. That is, the gate line wiring 70 integrally includes the gate pad wiring 68, which extends from the peripheral region 18 into the pad region 16. The gate line wiring 70 has a smaller width than the well region 54. The width of the gate line wiring 70 may be in a range of 10 μm to 100 μm, inclusive. Preferably, the width of the gate line wiring 70 is in a range of 15 μm to 60 μm, inclusive. The width of the gate line wiring 70 may be defined by a dimension orthogonal to the direction in which the gate line wiring 70 extends in plan view.

As shown in FIGS. 4 and 6, the gate connection wirings 72 are located inside the insulating film 60 and electrically connect the gate line wiring 70 to the trench gate structures 38. The gate connection wirings 72 extend from a portion of the gate line wiring 70 extending along the first side surface 12C (refer to FIG. 3). These gate connection wirings 72 extend toward the first end 38A of the trench gate structures 38 (refer to FIG. 2). Further, the gate connection wirings 72 extend from a portion of the gate line wiring 70 extending along the second side surface 12D (refer to FIG. 3). These gate connection wirings 72 extend toward the second end 38B of the trench gate structures 38 (refer to FIG. 2).

The gate connection wirings 72 are located at a side relatively close to the first side surface 12C, and are arranged at intervals along the gate line wiring 70. The gate connection wirings 72 extend from the side relatively close to the first side surface 12C toward the trench isolation structure 26. Preferably, the gate connection wirings 72 are arranged at equal intervals in the X-direction. The gate connection wirings 72 located on the main-surface insulating film 62 extend onto a portion of the trench isolation structure 26 located at a side relatively close to the first side surface 12C, and are connected to the isolation embedded electrode 32. In the first embodiment, the gate connection wirings 72 respectively cover the first ends 38A of the trench gate structures 38, and are connected to the gate embedded electrodes 44.

The gate connection wirings 72 are located at a side relatively close to the second side surface 12D, and are arranged at intervals along the gate line wiring 70. The gate connection wirings 72 extend from the side relatively close to the second side surface 12D toward the trench isolation structure 26. Preferably, the gate connection wirings 72 are arranged at equal intervals in the X-direction. The gate connection wirings 72 located on the main-surface insulating film 62 extend onto a portion of the trench isolation structure 26 located at a side relatively close to the second side surface 12D, and are connected to the isolation embedded electrode 32.

In the first embodiment, the gate connection wirings 72 respectively cover the second ends 38B of the trench gate structures 38, and are connected to the gate embedded electrodes 44. In the first embodiment, the gate wiring 66 is composed of the same conductive material as the isolation embedded electrode 32 and the gate embedded electrodes 44. The gate wiring 66 includes an extension extending from the isolation embedded electrode 32 and the gate embedded electrodes 44 onto the main-surface insulating film 62 (refer to FIG. 6).

As shown in FIG. 5, the semiconductor device 10 includes emitter openings 74 that expose the emitter regions 46 in a portion of the insulating film 60 that covers the IGBT region 14. The emitter openings 74 have a one-to-one relationship with the contact holes 48. The emitter openings 74 are continuous with the respective contact holes 48. The emitter openings 74 each have a strip shape that extends along a corresponding one of the contact holes 48 in plan view.

The semiconductor device 10 includes emitter connection electrodes 76 embedded in the insulating film 60 to be electrically connected to the emitter regions 46. The emitter connection electrodes 76 are embedded in the emitter openings 74. The emitter connection electrodes 76 extend from the emitter openings 74 into the contact holes 48 to be electrically connected to the emitter regions 46 and the contact regions 50.

The emitter connection electrodes 76 may each include at least one of a Ti-based metal film, a W-based metal film, an Al-based metal film, and a Cu-based metal film. In the first embodiment, each emitter connection electrode 76 has a multi-layer structure including a Ti-based metal film and a W-based metal film. The Ti-based metal film may include at least one of a pure Ti film (Ti purity of 99% or higher) and a Ti alloy film. The Ti alloy film may be a TiN film. The W-based metal film may include at least one of a pure W film (W purity of 99% or higher) and a W alloy film.

The Al-based metal film may include at least one of a pure Al film (Al purity of 99% or higher) and an Al alloy film. The Al alloy film may contain at least one of an AlCu alloy, an AlSi alloy, and an AlSiCu alloy. The Cu-based metal film may include at least one of a pure Cu film (Cu purity of 99% or higher) and a Cu alloy film. Hereinafter, it is assumed that a Ti-based metal film, a W-based metal film, an Al-based metal film, and a Cu-based metal film each include the above-described feature.

The semiconductor device 10 includes at least one (in the first embodiment, more than one) gate opening 78 that selectively exposes the gate line wiring 70 in a portion of the insulating film 60 that covers the gate line wiring 70. The number of gate openings 78 may be changed. In an example, a single gate opening 78 may be formed in the insulating film 60.

As shown in FIGS. 4 and 5, the gate openings 78 are separated from both the inner edge and the outer edge of the gate line wiring 70, and expose an inner part of the gate line wiring 70. The gate openings 78 are separated from each other from a side relatively close to the IGBT region 14 toward a side relatively close to the peripheral edge of the chip 12. The gate openings 78 each have a strip shape that extends along the gate line wiring 70. The gate openings 78 may each have an endless or open-ended strip shape that surrounds the IGBT region 14. In an example, the gate openings 78 each have a loop shape (in the first embodiment, a quadrangular loop) that surrounds the IGBT region 14.

Although not shown in the drawings, the semiconductor device 10 may include at least one (in the first embodiment, more than one) gate opening 78 that selectively exposes the gate pad wiring 68 in a portion of the insulating film 60 that covers the gate pad wiring 68.

The semiconductor device 10 includes at least one (in the first embodiment, more than one) gate connection electrode 80 embedded in the insulating film 60 to be electrically connected to the gate line wiring 70. The gate connection electrodes 80 may each include at least one of a Ti-based metal film, a W-based metal film, an Al-based metal film, and a Cu-based metal film. In the first embodiment, each gate connection electrode 80 has a multi-layer structure including a Ti-based metal film and a W-based metal film.

The gate connection electrodes 80 have a one-to-one relationship with the gate openings 78. The gate connection electrodes 80 are electrically connected to the gate line wiring 70 in the respective gate openings 78. In a case in which a gate opening 78 is formed in the insulating film 60 to expose the gate pad wiring 68, the gate connection electrode 80 may be formed in the gate opening 78 to be electrically connected to the gate pad wiring 68.

The semiconductor device 10 includes multiple well openings 82 that selectively expose the well region 54 in a portion of the insulating film 60 that covers the peripheral region 18. The well openings 82 include at least one (in the first embodiment, more than one) first well opening 82A that exposes the well region 54 at a side relatively close to the IGBT region 14, and at least one (in the first embodiment, more than one) second well opening 82B that exposes the well region 54 at a side relatively close to the peripheral edge of the chip 12. The number of first well openings 82A and the number of second well openings 82B may be changed. In an example, a single first well opening 82A may be formed in the insulating film 60. In an example, a single second well opening 82B may be formed in the insulating film 60.

The first well openings 82A are separated from each other in a region extending from an intermediate part of the well region 54 in the width direction toward the inner edge 54A of the well region 54. The first well openings 82A selectively expose a portion of the well region 54 located relatively close to the inner edge 54A. More specifically, the first well openings 82A are separated from each other in a region extending from the gate line wiring 70 toward the inner edge 54A of the well region 54 to selectively expose an inner edge portion of the well region 54.

As shown in FIGS. 4 and 5, the first well openings 82A are separated from each other from a side relatively close to the IGBT region 14 toward the peripheral edge of the chip 12. The first well openings 82A each have a strip shape that extends along the well region 54. The first well openings 82A each include a portion extending along the well region 54 in the X-direction and a portion extending along the well region 54 in the Y-direction.

As shown in FIG. 4, the first well openings 82A each include opening segments 82AA that are separated from one another. In the portion of the first well opening 82A extending in the X-direction, the opening segments 82AA expose the well region 54 between the gate connection wirings 72. In other words, the opening segments 82AA are separated from the gate connection wirings 72 so as not to expose the gate connection wirings 72. The opening segments 82AA are formed in a region surrounded by the trench isolation structure 26 (trench gate structures 38), the gate line wiring 70, and the gate connection wirings 72. The opening segments 82AA each have a strip shape that extends in the X-direction.

As shown in FIG. 5, the second well openings 82B are separated from each other in a region extending from an intermediate part of the well region 54 in the width direction toward the outer edge 54B of the well region 54. The second well openings 82B selectively expose a portion of the well region 54 located relatively close to the outer edge 54B. More specifically, the second well openings 82B are separated from each other in a region extending from the gate line wiring 70 toward the outer edge 54B of the well region 54 to selectively expose an outer edge portion of the well region 54.

As shown in FIGS. 4 and 5, the second well openings 82B are separated from each other from a side relatively close to the IGBT region 14 toward the peripheral edge of the chip 12. The second well openings 82B each have a strip shape that extends along the well region 54. The second well openings 82B may each have an endless or open-ended strip shape that surrounds the IGBT region 14. In an example, the second well openings 82B each have a loop shape (in the first embodiment, a quadrangular loop) that surrounds the IGBT region 14.

As shown in FIG. 5, the semiconductor device 10 includes well connection electrodes 84 embedded in the insulating film 60 to be electrically connected to the well region 54. The well connection electrodes 84 may each include at least one of a Ti-based metal film, a W-based metal film, an Al-based metal film, and a Cu-based metal film. In the first embodiment, each well connection electrode 84 has a multi-layer structure including a Ti-based metal film and a W-based metal film.

The well connection electrodes 84 include at least one (in the first embodiment, more than one) first well connection electrode 84A and at least one (in the first embodiment, more than one) second well connection electrode 84B. Each first well connection electrode 84A is connected to the well region 54 at a side of the well region 54 relatively close to the inner edge 54A (IGBT region 14). Each second well connection electrode 84B is connected to the well region 54 at a side of the well region 54 relatively close to the outer edge 54B (peripheral edge of chip 12). The number of first well connection electrodes 84A and the number of second well connection electrodes 84B may be changed. In an example, the number of first well connection electrodes 84A may be one. In an example, the number of second well connection electrodes 84B may be one.

The first well connection electrodes 84A have a one-to-one relationship with the first well openings 82A. Specifically, the first well connection electrodes 84A are separated from each other in a region extending from an intermediate part of the well region 54 in the width direction toward the inner edge 54A of the well region 54. The first well connection electrodes 84A are electrically connected to a region of the well region 54 located relatively close to the inner edge 54A. More specifically, the first well connection electrodes 84A are separated from each other in a region extending from the gate line wiring 70 toward the inner edge 54A of the well region 54 to be electrically connected to the inner edge portion of the well region 54.

The second well connection electrodes 84B have a one-to-one relationship with the second well openings 82B. In other words, the second well connection electrodes 84B are separated from each other in a region extending from an intermediate part of the well region 54 in the width direction toward the outer edge 54B of the well region 54. The width direction of the well region 54 may be defined by a direction orthogonal to the direction in which the well region 54 extends in plan view. The second well connection electrodes 84B are electrically connected to a region of the well region 54 located relatively close to the outer edge 54B. More specifically, the second well connection electrodes 84B are separated from each other in a region extending from the gate line wiring 70 toward the outer edge 54B of the well region 54 to be electrically connected to the outer edge portion of the well region 54.

As shown in FIG. 1, the semiconductor device 10 includes a gate electrode 86 formed on the insulating film 60. The gate electrode 86 is composed of a conductive material different from that of the gate wiring 66 (refer to FIG. 3). In the first embodiment, the gate electrode 86 is formed by a metal film. The gate electrode 86 has a lower resistance than the gate wiring 66. The gate electrode 86 may be referred to as a “gate metal.” The gate electrode 86 may include at least one of a Ti-based metal film, a W-based metal film, an Al-based metal film, and a Cu-based metal film. In the first embodiment, the gate electrode 86 has a multi-layer structure including a Ti-based metal film and an Al-based metal film.

As shown in FIGS. 1 and 2, the gate electrode 86 includes a gate pad electrode 88 and a gate line electrode 90. The gate line electrode 90 may be referred to as a “gate finger electrode.” The gate pad electrode 88 is formed on a portion of the insulating film 60 that covers the gate pad wiring 68. In an example, the gate pad electrode 88 has a polygonal shape (in the first embodiment, a quadrangular shape) that matches the pad region 16 in plan view.

The gate pad electrode 88 faces the gate pad wiring 68 (refer to FIG. 3) with part (interlayer insulating film 64) of the insulating film 60 located in between in the thickness direction of the chip 12. The gate pad electrode 88 faces the pad well region 52 (refer to FIG. 3) with the insulating film 60 and the gate pad wiring 68 located in between in the thickness direction of the chip 12. In a case in which the gate connection electrode 80 is connected to the gate pad wiring 68, the gate pad electrode 88 is electrically connected to the gate pad wiring 68 via the gate connection electrode 80 (refer to FIG. 5).

The gate pad electrode 88 may have a surface area that is greater than or equal to that of the pad region 16 in plan view. Alternatively, the gate pad electrode 88 may have a surface area that is less than that of the pad region 16 in plan view. The gate pad electrode 88 may have a surface area that is greater than or equal to that of the gate pad wiring 68 in plan view. Alternatively, the gate pad electrode 88 may have a surface area that is less than that of the gate pad wiring 68 in plan view.

As shown in FIGS. 5 to 7, the gate line electrode 90 is formed on a portion of the insulating film 60 that covers the gate line wiring 70. The gate line electrode 90 is formed integrally with the gate pad electrode 88 (refer to FIG. 2). The gate line electrode 90 has a strip shape and extends from the gate pad electrode 88 onto the insulating film 60. In the first embodiment, the gate line electrode 90 extends from the gate pad electrode 88 onto the insulating film 60 in a region located between the first well connection electrodes 84A and the second well connection electrodes 84B.

The gate line electrode 90 is separated from both the first well connection electrodes 84A and the second well connection electrodes 84B. The gate line electrode 90 covers the gate connection electrodes 80. In other words, the gate line electrode 90 is separated from the first well connection electrodes 84A toward the outer edge 54B of the well region 54 (peripheral edge of chip 12). The gate line electrode 90 is separated from the second well connection electrodes 84B toward the inner edge 54A of the well region 54 (IGBT region 14). The gate line electrode 90 is electrically connected to the gate line wiring 70 via the gate connection electrodes 80.

The gate line electrode 90 faces the gate line wiring 70 with part of the insulating film 60 located in between in the thickness direction of the chip 12. The gate line electrode 90 faces the well region 54 with the insulating film 60 and the gate line wiring 70 located in between in the thickness direction of the chip 12. The gate line electrode 90 has a smaller width than the well region 54. Preferably, the gate line electrode 90 has a smaller width than the gate line wiring 70. The width of the gate line electrode 90 may be changed. For example, the gate line electrode 90 may have a width that is greater than or equal to that of the gate line wiring 70.

As shown in FIGS. 1 and 2, the gate line electrode 90 has a strip shape that extends along the gate line wiring 70 in plan view. Preferably, the gate line electrode 90 defines the IGBT region 14 from multiple directions in plan view. In the first embodiment, the gate line electrode 90 has a strip shape that extends along the first to fourth side surfaces 12C to 12F in plan view. The gate line electrode 90 defines the IGBT region 14 from four directions. The gate line electrode 90 may have an endless or open-ended strip shape that surrounds the IGBT region 14. In an example, the gate line electrode 90 has a loop shape (in the first embodiment, a quadrangular loop) that surrounds the IGBT region 14, and includes two open ends 90A at a portion extending along the fourth side surface 12F.

The semiconductor device 10 includes an emitter electrode 92 formed on the insulating film 60 and separated from the gate electrode 86. The emitter electrode 92 is composed of a conductive material different from that of the gate wiring 66. In the first embodiment, the emitter electrode 92 is formed by a metal film. The emitter electrode 92 has a lower resistance than the gate wiring 66 (refer to FIG. 3). The emitter electrode 92 may be referred to as an “emitter metal.” The emitter electrode 92 may include at least one of a Ti-based metal film, a W-based metal film, an Al-based metal film, and a Cu-based metal film. In the first embodiment, the emitter electrode 92 has a multi-layer structure including a Ti-based metal film and an Al-based metal film. That is, the emitter electrode 92 is composed of the same material as the gate electrode 86.

The emitter electrode 92 includes an emitter pad electrode 94 and an emitter line electrode 96. The emitter line electrode 96 may be referred to as an “emitter finger electrode.” The emitter pad electrode 94 is formed on a portion of the insulating film 60 that covers the IGBT region 14. In an example, the emitter pad electrode 94 is separated from the gate pad electrode 88 and the gate line electrode 90. The emitter pad electrode 94 has a polygonal shape including a recess recessed in correspondence with the gate pad electrode 88 in plan view.

As shown in FIG. 5, the emitter pad electrode 94 covers the trench gate structures 38 and the emitter connection electrodes 76 altogether. The emitter pad electrode 94 faces the trench gate structures 38 with the insulating film 60 located in between. The emitter pad electrode 94 is electrically connected to the emitter regions 46 via the emitter connection electrodes 76. The emitter pad electrode 94 includes an emitter extension 94A extending out of the IGBT region 14 into the peripheral region 18. The emitter extension 94A extends across a region directly above the trench isolation structure 26 so as to face the well region 54 in the thickness direction of the chip 12.

The emitter extension 94A covers a portion of the well region 54 located closer to the inner edge 54A than an intermediate portion of the well region 54 in the width direction is. More specifically, the emitter extension 94A is separated from the gate line electrode 90 toward the IGBT region 14, and collectively covers the first well connection electrodes 84A and the inner edge portion of the well region 54. Accordingly, the emitter pad electrode 94 is electrically connected to the inner edge portion of the well region 54 via the first well connection electrodes 84A.

As shown in FIGS. 1 and 5, the emitter line electrode 96 is formed integrally with the emitter pad electrode 94. The emitter line electrode 96 extends from the emitter pad electrode 94 onto the insulating film 60. Specifically, the emitter line electrode 96 has a strip shape and extends from the emitter pad electrode 94 onto the insulating film 60 located in the peripheral region 18. The emitter line electrode 96 extends across a region between the two open ends 90A of the gate line electrode 90.

As shown in FIGS. 5 to 7, the emitter line electrode 96 extends onto a portion of the insulating film 60 that covers the well region 54. In other words, the emitter line electrode 96 faces the well region 54 with the insulating film 60 located in between in the thickness direction of the chip 12. The emitter line electrode 96 is separated from the gate line electrode 90 toward the outer edge 54B of the well region 54 (peripheral edge of chip 12) to cover the second well connection electrodes 84B. Accordingly, the emitter line electrode 96 is electrically connected to the outer edge portion of the well region 54 via the second well connection electrodes 84B.

As shown in FIGS. 1 and 2, the emitter line electrode 96 has a strip shape that extends along the outer edge 54B of the well region 54 in plan view. Preferably, the emitter line electrode 96 defines the IGBT region 14 from multiple directions in plan view. In the first embodiment, the emitter line electrode 96 has a strip shape that extends along the first to fourth side surfaces 12C to 12F in plan view. The emitter line electrode 96 defines the IGBT region 14 from four directions. The emitter line electrode 96 may have an endless or open-ended strip shape that surrounds the IGBT region 14. In an example, the emitter line electrode 96 has a loop shape (in the first embodiment, a quadrangular loop) that surrounds the IGBT region 14.

As shown in FIG. 8, the insulating film 60 includes at least one (in the first embodiment, more than one) field opening 98 that selectively exposes the field regions 56 in the peripheral region 18. The field openings 98 expose a corresponding field region 56 in a many-to-one relationship. Alternatively, a single field opening 98 may expose the corresponding field region 56 in a one-to-one relationship. The field openings 98 each have a strip shape that extends along a corresponding one of the field regions 56. In an example, the field openings 98 each have a loop shape (in the first embodiment, a quadrangular loop) that extends along a corresponding one of the field regions 56.

The semiconductor device 10 includes at least one (in the first embodiment, more than one) field connection electrode 100 embedded in the insulating film 60 to be electrically connected to a corresponding one of the field regions 56. The field connection electrodes 100 may each include at least one of a Ti-based metal film, a W-based metal film, an Al-based metal film, and a Cu-based metal film. In the first embodiment, each field connection electrode 100 has a multi-layer structure including a Ti-based metal film and a W-based metal film.

The field connection electrodes 100 have a one-to-one relationship with the field openings 98. The field connection electrodes 100 are electrically connected to the respective field regions 56 in the respective field openings 98. In the first embodiment, the field connection electrodes 100 are electrically floating.

The semiconductor device 10 includes field electrodes 102 formed on the insulating film 60 in the peripheral region 18. The field electrodes 102 may each include at least one of a Ti-based metal film, a W-based metal film, an Al-based metal film, and a Cu-based metal film. In an example, each field electrode 102 may have a multi-layer structure including a Ti-based metal film and a W-based metal film. The field electrodes 102 are electrically floating.

The field electrodes 102 have a one-to-one relationship with the field regions 56. The field electrodes 102 each collectively cover a corresponding field connection electrodes 100. The field electrodes 102 are electrically connected to the respective field regions 56 via the respective field connection electrodes 100.

The field electrodes 102 each have a strip shape that extends along a correspondence one of the field regions 56. In an example, the field electrodes 102 each have a loop shape (in the first embodiment, a quadrangular loop) that extends along a corresponding one of the field regions 56.

The field electrodes 102 include inner field electrodes 102A to 102C corresponding to the inner field regions 56A to 56C, and an outermost field electrode 102D corresponding to the outermost field region 56D. The outermost field electrode 102D includes a field extension 102E that extends toward the peripheral edge of the chip 12. Accordingly, the outermost field electrode 102D has a greater width than the inner field electrodes 102A to 102C. In an example, the inner field electrodes 102A to 102C have the same width.

The insulating film 60 includes a channel stop opening 104 that exposes the channel stop region 58 in the peripheral region 18. The channel stop opening 104 has a strip shape that extends along the channel stop region 58. In an example, the channel stop opening 104 has a loop shape (in the first embodiment, a quadrangular loop) that extends along the channel stop region 58. The channel stop opening 104 is continuous with the peripheral edge of the chip 12.

The semiconductor device 10 includes a channel stop electrode 106 formed on the insulating film 60 in the peripheral region 18. The channel stop electrode 106 may include at least one of a Ti-based metal film, a W-based metal film, an Al-based metal film, and a Cu-based metal film. In the first embodiment, the channel stop electrode 106 may have a multi-layer structure including a Ti-based metal film and a W-based metal film. The channel stop electrode 106 is electrically floating.

The channel stop electrode 106 has a strip shape that extends along the channel stop region 58. In an example, the channel stop electrode 106 has a loop shape (in the first embodiment, a quadrangular loop) that extends along the channel stop region 58. The channel stop electrode 106 formed on the insulating film 60 extends into the channel stop opening 104 to be electrically connected to the channel stop region 58. The channel stop electrode 106 may be separated from the peripheral edge of the chip 12 toward the IGBT region 14 to expose the peripheral edge portion (channel stop region 58) of the first main surface 12A.

The semiconductor device 10 includes a collector electrode 108 formed on the second main surface 12B. In an example, the collector electrode 108 covers the second main surface 12B. The collector electrode 108 is electrically connected to the collector region 24 exposed from the second main surface 12B. The collector electrode 108 is in ohmic contact with the collector region 24. The collector electrode 108 may cover the entire second main surface 12B to be continuous with the peripheral edge (first to fourth side surfaces 12C to 12F) of the chip 12.

The collector electrode 108 may have a single-layer structure or a multi-layer structure including at least one of a Ti film, a Ni film, a Pd film, an Au film, an Ag film, and an Al film. Preferably, the collector electrode 108 includes a Ti film that directly covers at least the second main surface 12B. The collector electrode 108 may have a multi-layer structure in which, for example, a Ti film, a Ni film, a Pd film, and an Au film are stacked in this order on the second main surface 12B.

### Cathode Region

As shown in FIG. 8, the semiconductor device 10 includes an n-type cathode region 110 formed in a surface region of the second main surface 12B in the peripheral region 18. The cathode region 110 has an n-type impurity concentration that is higher than a p-type impurity concentration of the collector region 24. The cathode region 110 is a region in which the conductivity type of the collector region 24 is changed from p-type to n-type. Preferably, the cathode region 110 has a higher n-type impurity concentration than the drift region 20 (buffer region 22).

The cathode region 110 forms a layer that extends along the second main surface 12B. The cathode region 110 is exposed from the second main surface 12B. The cathode region 110 extends through the collector region 24 to be connected to the buffer region 22. The cathode region 110 is electrically connected to the collector electrode 108. The cathode region 110 is in ohmic contact with the collector electrode 108. The cathode region 110 forms a diode 112 together with the well region 54. The diode 112 serves as a freewheeling diode for the IGBT structure 34.

When a forward voltage VF of the diode 112 is applied between the emitter electrode 92 and the collector electrode 108, a forward current IF flows through the diode 112. For example, the forward current IF flows from the second well connection electrode 84B to the cathode region 110.

In plan view, the cathode region 110 is located closer to the peripheral edge of the chip 12 than the well region 54 is. More specifically, in plan view, the cathode region 110 is located closer to the peripheral edge of the chip 12 than the outer edge 54B of the well region 54 is. In other words, in plan view, the cathode region 110 is located closer to the field regions 56 than the well region 54 is.

In an example, the cathode region 110 is separated from the well region 54 toward the peripheral edge of the chip 12 so as not to face the well region 54 in the thickness direction of the chip 12. Accordingly, the cathode region 110 is separated from the IGBT region 14 toward the peripheral edge of the chip 12 so as not to face the IGBT region 14 in the thickness direction of the chip 12. In other words, the cathode region 110 is formed only in the peripheral region 18 and is absent within the IGBT region 14. This reduces electrical interference between the IGBT region 14 and the diode 112.

The cathode region 110 may have an endless or open-ended strip shape that surrounds the IGBT region 14 in plan view. The cathode region 110 may have an endless or open-ended strip shape that surrounds the well region 54 in plan view. In an example, the cathode region 110 has a loop shape (in the first embodiment, a quadrangular loop) that surrounds the well region 54. The cathode region 110 of the first embodiment has a quadrangular loop shape with rounded corners in plan view.

Width W1 of the cathode region 110 is less than width WP of the well region 54. The width W1 of the cathode region 110 is less than distance Dwc between the well region 54 and the channel stop region 58. The width W1 of the cathode region 110 is less than width WT of the entire field regions 56. In the first embodiment, the width W1 of the cathode region 110 is equal to the width of the inner field region 56A. In the first embodiment, the width of each of the inner field regions 56B and 56C is equal to the width of the inner field region 56A. Accordingly, the width W1 of the cathode region 110 is also equal to the width of each of the inner field regions 56B and 56C. That is, in the first embodiment, the width W1 of the cathode region 110 is equal to the width WF of the field region 56.

The width W1 of the cathode region 110 may be changed. For example, the width W1 of the cathode region 110 may be greater than the width of the inner field region 56A. In this case, the width W1 of the cathode region 110 is, for example, less than two times the width of the inner field region 56A. The width W1 of the cathode region 110 may be greater than the width WF of the field region 56. In this case, the width W1 of the cathode region 110 is, for example, less than two times the width WF of the field region 56.

The cathode region 110 is formed to face at least one of the field regions 56 in the thickness direction (Z-direction) of the chip 12. The cathode region 110 is separated from the channel stop region 58 toward the field regions 56 so as not to face the channel stop region 58 in the thickness direction of the chip 12. In other words, the cathode region 110 is formed to face a position separated from the channel stop region 58 toward the field regions 56 in the thickness direction of the chip 12. In this manner, in plan view, the cathode region 110 is located closer to the peripheral edge of the chip 12 than the well region 54 is, and is located closer to the well region 54 than the channel stop region 58 is. Accordingly, the IGBT region 14 and the well region 54 both face the collector region 24 in the thickness direction of the chip 12.

In an example, the cathode region 110 may be formed to face one of the field regions 56 located relatively close to the well region 54 in the thickness direction of the chip 12. In other words, the cathode region 110 may be formed to face one of the inner field regions 56A to 56C in the thickness direction of the chip 12. In the first embodiment, the cathode region 110 is formed to face the inner field region 56B in the thickness direction of the chip 12. In a case in which the loop-shaped cathode region 110 faces one of the field regions 56 in the thickness direction of the chip 12, the cathode region 110 may face the one of the field regions 56 along the entire perimeter of that field region 56.

### Method for Setting Position of Cathode Region

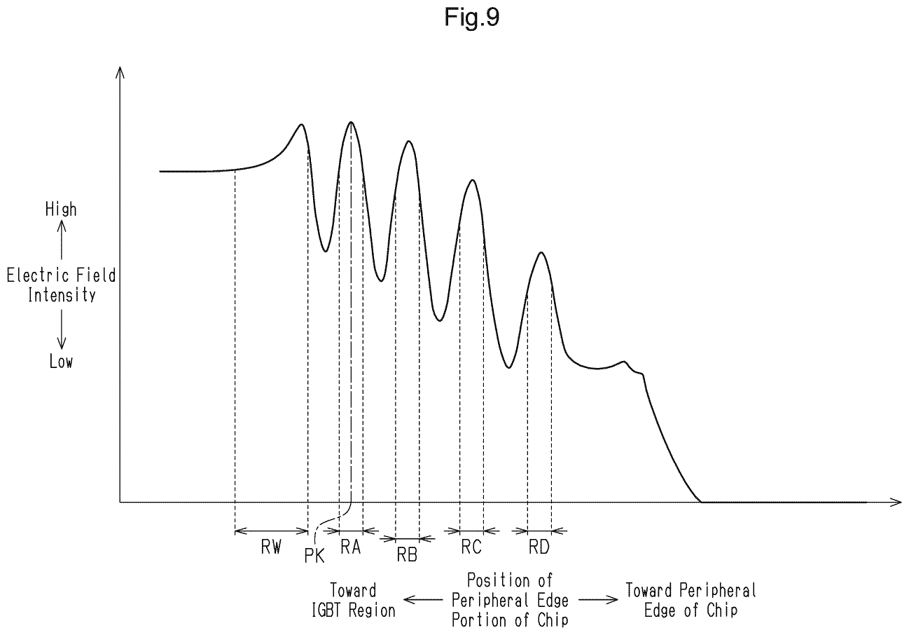

A method for setting the position of the cathode region 110 will now be described with reference to FIGS. 9 to 11. In the description hereafter, components of the semiconductor device 10 will be denoted by the reference characters assigned to the components of the semiconductor device 10 shown in FIGS. 1 to 8.

FIGS. 9 to 11 are graphs of electric field intensity in the peripheral region 18 when a predetermined collector-emitter voltage Vce is applied. The predetermined collector-emitter voltage Vce is, for example, 650 V.

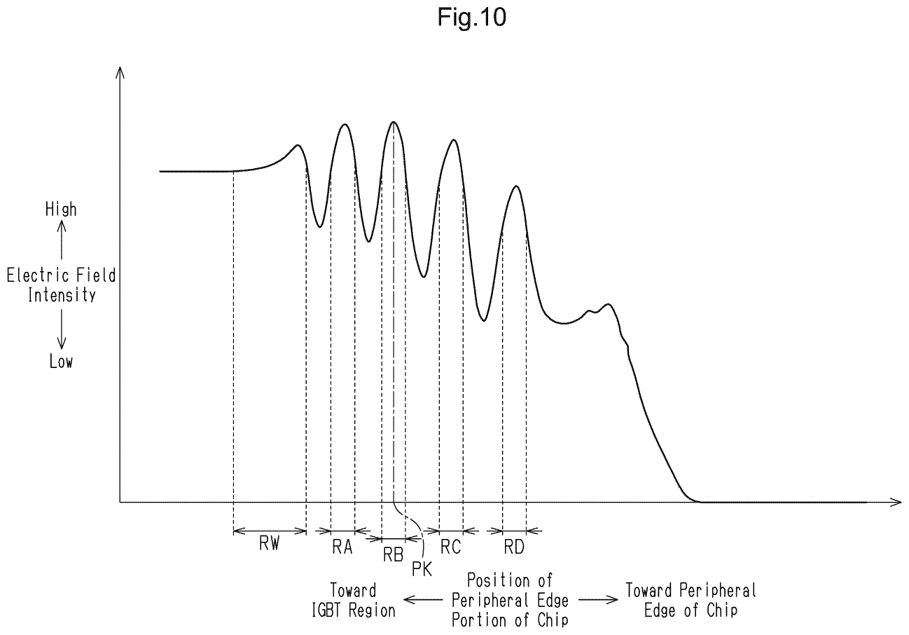

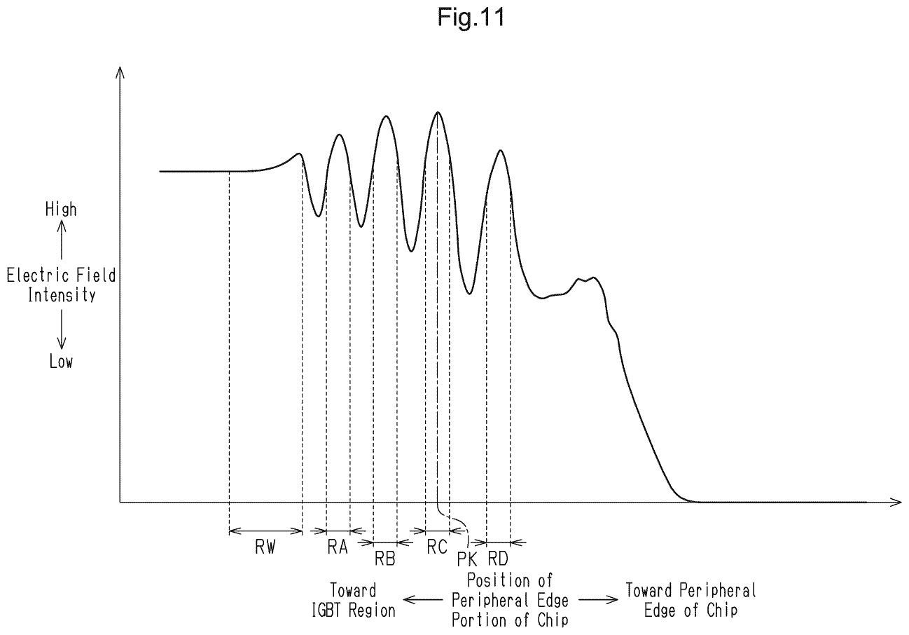

FIGS. 9 to 11 illustrate the electric field intensity in accordance with different spacings of the field regions 56. The graph of FIG. 9 shows a first example of the electric field intensity in the peripheral region in a case in which the spacing of the field regions 56 corresponds to reference widths. The graph of FIG. 10 shows a second example of the electric field intensity in the peripheral region in a case in which the spacing of the field regions 56 corresponds to first intervals that are less than the reference widths. The graph of FIG. 11 shows a third example of the electric field intensity in the peripheral region in a case in which the spacing of the field regions 56 corresponds to second intervals that are less than the first intervals. In the graphs of FIGS. 9 to 11, the field regions 56 each have a constant width. The width of each field region 56 is set to 10 μm.

In an example of the reference widths, the distance between the inner field region 56A and the inner field region 56B is 18 μm, the distance between the inner field region 56B and the inner field region 56C is 21 μm, and the distance between the inner field region 56C and the outermost field region 56D is 24 μm. Further, the distance between the outer edge 54B of the well region 54 and the inner field region 56A is 16 μm.

In an example of the first intervals, the distance between the inner field region 56A and the inner field region 56B is 15 μm, the distance between the inner field region 56B and the inner field region 56C is 18 μm, and the distance between the inner field region 56C and the outermost field region 56D is 21 μm. Further, the distance between the outer edge 54B of the well region 54 and the inner field region 56A is 13 μm.

In an example of the second intervals, the distance between the inner field region 56A and the inner field region 56B is 13 μm, the distance between the inner field region 56B and the inner field region 56C is 16 μm, and the distance between the inner field region 56C and the outermost field region 56D is 19 μm. Further, the distance between the outer edge 54B of the well region 54 and the inner field region 56A is 11 μm.

In FIGS. 9 to 11, range RW along the horizontal axis indicates a portion of the peripheral region 18 in which the outer edge portion of the well region 54 is located. In FIGS. 9 to 11, range RA along the horizontal axis indicates a portion of the peripheral region 18 in which the inner field region 56A is located. In FIGS. 9 to 11, range RB along the horizontal axis indicates a portion of the peripheral region 18 in which the inner field region 56B is located. In FIGS. 9 to 11, range RC along the horizontal axis indicates a portion of the peripheral region 18 in which the inner field region 56C is located. In FIGS. 9 to 11, range RD along the horizontal axis indicates a portion of the peripheral region 18 in which the outermost field region 56D is located.

As shown in FIGS. 9 to 11, the electric field intensity has peaks in the outer edge portion of the well region 54, the inner field regions 56A to 56C, and the outermost field region 56D. In other words, the electric field intensity is relatively low in regions between adjacent field regions 56. Accordingly, it is not preferred that the cathode region 110 is formed to face only the regions between adjacent field regions 56 in the thickness direction. More specifically, it is preferred that the cathode region 110 is partially or entirely formed to face the inner field regions 56A to 56C and the outermost field region 56D in the thickness direction.

In the first example shown in FIG. 9, position PK of the maximum electric field intensity is located in the range RA of the inner field region 56A. In the second example shown in FIG. 10, position PK of the maximum electric field intensity is located in the range RB of the inner field region 56B. In the third example shown in FIG. 11, position PK of the maximum electric field intensity is located in the range RC of the inner field region 56C. In this manner, as the spacing of the field regions 56 narrows, the position PK of the maximum electric field intensity moves toward the peripheral edge of the chip 12. Accordingly, the position PK of the maximum electric field intensity can be adjusted by changing the spacing of the field regions 56.

An example assumes that the field regions 56 include a specific field region in which an electric field having the maximum intensity occurs when the collector-emitter voltage Vce is applied. In this case, the cathode region 110 is formed to face the specific field region in the thickness direction of the chip 12.

More specifically, in the first example shown in FIG. 9, the position PK of the maximum electric field intensity is in the inner field region 56A, and therefore, the specific field region is the inner field region 56A. Accordingly, the cathode region 110 is formed directly below the inner field region 56A.

In the second example shown in FIG. 10, the position PK of the maximum electric field intensity is in the inner field region 56B, and therefore, the specific field region is the inner field region 56B. Accordingly, the cathode region 110 is formed directly below the inner field region 56B.

In the third example shown in FIG. 11, the position PK of the maximum electric field intensity is in the inner field region 56C, and therefore, the specific field region is the inner field region 56C. Accordingly, the cathode region 110 is formed directly below the inner field region 56C.

The spacing of the field regions 56 may be adjusted at the design stage so that the position PK of the maximum electric field intensity is at a desired location. Specifically, the spacing of the field regions 56 is adjusted at the design stage to set a specific field region in which the position PK of the maximum electric field intensity is located. Then, the cathode region 110 is formed to face the specific field region in the thickness direction. As a result, the cathode region 110 is located at a position where the electric field intensity becomes highest when the collector-emitter voltage Vce is applied.

The method for setting the position of the cathode region 110 will now be described in consideration of the diode characteristics.

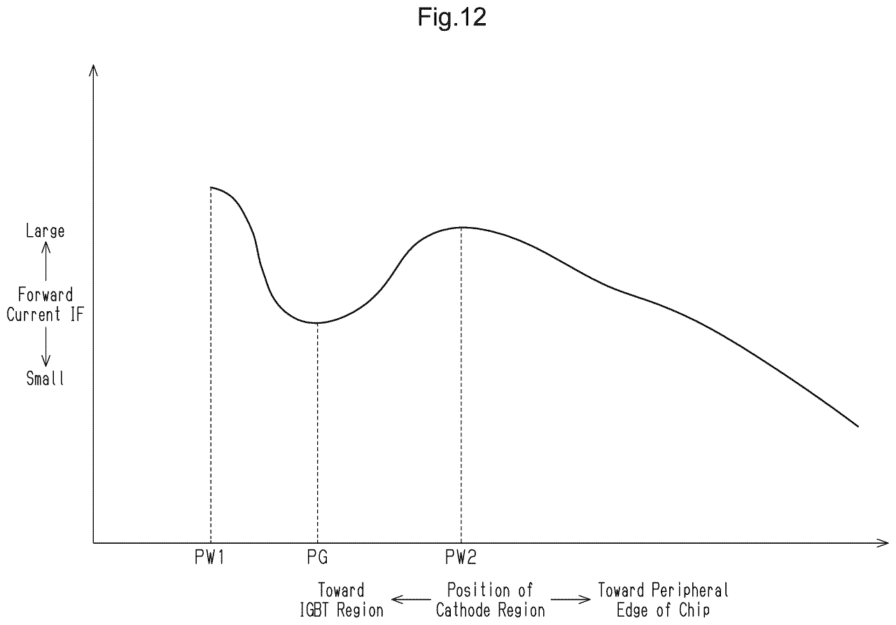

FIG. 12 is a graph of the forward current IF of the diode 112 relative to the position of the cathode region 110. The vertical axis in FIG. 12 indicates the forward current IF (A). The horizontal axis in FIG. 12 indicates the position of the cathode region 110. The graph of FIG. 12 shows changes in the forward current IF when the position of the cathode region 110 is changed from directly below the well region 54 to directly below the inner field region 56C. The width of the cathode region 110 is fixed to a constant value (in FIG. 12, 10 μm).

With respect to the horizontal axis in FIG. 12, first well reference position PW1 is located directly below the first well connection electrode 84A. In a case in which only one first well connection electrode 84A is formed, the first well reference position PW1 is located directly below the center of the first well connection electrode 84A. In a case in which two or more first well connection electrodes 84A are formed, the first well reference position PW1 is located directly below a midpoint between an innermost first well connection electrode 84A located relatively close to the IGBT region 14 and an outermost first well connection electrode 84A located relatively close to the peripheral edge of the chip 12. In other words, the first well reference position PW1 faces the first well connection electrode 84A in the thickness direction of the chip 12.

A second well reference position PW2 is located directly below the second well connection electrode 84B. In a case in which only one second well connection electrode 84B is formed, the second well reference position PW2 is located directly below the center of the second well connection electrode 84B. In a case in which two or more second well connection electrodes 84B are formed, the second well reference position PW2 is located directly below a midpoint between an innermost second well connection electrode 84B located relatively close to the IGBT region 14 and an outermost second well connection electrode 84B located relatively close to the peripheral edge of the chip 12. In other words, the second well reference position PW2 faces the second well connection electrode 84B in the thickness direction of the chip 12. The first well reference position PW1 and the second well reference position PW2 are both examples of a “well reference position.”

As shown in FIG. 12, the forward current IF gradually decreases as the position of the cathode region 110 is changed from the first well reference position PW1 toward gate reference position PG. The forward current IF gradually increases as the position of the cathode region 110 is changed from the gate reference position PG toward the second well reference position PW2. The forward current IF gradually decreases as the position of the cathode region 110 is changed from the second well reference position PW2 toward the peripheral edge of the chip 12. In this manner, the forward current IF gradually decreases as the position of the cathode region 110 is changed from the outer edge 54B of the well region 54 toward the channel stop region 58. In other words, the forward current IF gradually increases as the position of the cathode region 110 is changed from the channel stop region 58 toward the outer edge 54B of the well region 54. Accordingly, the forward current IF increases as the position of the cathode region 110 is changed from the outermost field region 56D of the field regions 56 toward the well region 54. More specifically, in a case in which the cathode region 110 is formed directly below the inner field regions 56A to 56C, the forward current IF is greater than a case in which the cathode region 110 is formed directly below the outermost field region 56D. In addition, in a case in which the cathode region 110 is formed directly below the inner field region 56B, the forward current IF is greater than a case in which the cathode region 110 is formed directly below the inner field region 56C. In a case in which the cathode region 110 is formed directly below the inner field region 56A, the forward current IF is greater than a case in which the cathode region 110 is formed directly below the inner field region 56B.

In the second example shown in FIG. 10, there is a relatively small difference between the peak value of the electric field intensity in the inner field region 56A and the peak value of the electric field intensity in the inner field region 56B, in which the position PK of the maximum electric field intensity is located. In this case, if the cathode region 110 is located directly below the inner field region 56A, the forward current IF becomes larger than when the cathode region 110 is located directly below the inner field region 56B. Thus, in the second example, the cathode region 110 may be formed directly below the inner field region 56A, so that the electric field in the inner field region 56A is mitigated and the forward current IF is increased.

In the third example shown in FIG. 11, there is a relatively small difference between the peak value of the electric field intensity in the inner field region 56B and the peak value of the electric field intensity in the inner field region 56C, in which the position PK of the maximum electric field intensity is located. In this case, if the cathode region 110 is located directly below the inner field region 56B, the forward current IF becomes larger than when the cathode region 110 is located directly below the inner field region 56C. Thus, in the third example, the cathode region 110 may be formed directly below the inner field region 56B, so that the electric field in the inner field region 56B is mitigated and the forward current IF is increased. As described above, the position of the cathode region 110 may be set in consideration of a balance between mitigation of electric field concentration in the peripheral region 18 and an increase in the forward current IF.

In another example of the method for setting the position of the cathode region 110, the spacing of the field regions 56 may be increased at the design stage so that the position PK of the maximum electric field intensity is located in the inner field region 56A. That is, the spacing of the field regions 56 is set to the reference widths. In this case, the cathode region 110 is formed to face the inner field region 56A of the field regions 56 located closest to the well region 54 in the thickness direction. This mitigates electric field concentration in the peripheral region 18 and increases the forward current IF.

### Operation and Advantages of the Embodiment

The semiconductor device 10 in accordance with the first embodiment has the following operation and advantages.
(1-1) The semiconductor device 10 includes the chip 12, the peripheral region 18, the IGBT region 14, the well region 54, the field regions 56, the cathode region 110, the insulating film 60, the emitter electrode 92, and the collector electrode 108. The chip 12 includes the first main surface 12A and the second main surface 12B opposite of the first main surface 12A. The peripheral region 18 is located in the peripheral edge portion of the first main surface 12A. The IGBT region 14 is located at an inner side of the peripheral region 18 of the first main surface 12A. The well region 54 is of the first conductivity type and formed in a surface region of the first main surface 12A in the peripheral region 18 to define the IGBT region 14. The field regions 56 are of the first conductivity type and formed in a surface region of the first main surface 12A in the peripheral region 18. The field regions 56 are separated from the well region 54 toward the peripheral edge of the chip 12 and are spaced apart from each other. The cathode region 110 is of the second conductivity type and formed in a surface region of the second main surface 12B in the peripheral region 18. The cathode region 110 forms the diode 112 together with the well region 54. The insulating film 60 covers at least the well region 54. The emitter electrode 92 is formed on the insulating film 60 to be electrically connected to the well region 54. The collector electrode 108 is formed on the second main surface 12B to be electrically connected to the cathode region 110. The cathode region 110 is located closer to the peripheral edge of the chip 12 than the well region 54 is. The cathode region 110 is formed to face at least one of the field regions 56 in the thickness direction of the chip 12.

With this configuration, the cathode region 110 faces at least one of the field regions 56 in the thickness direction of the chip 12, thereby mitigating electric field concentration in the field regions 56. Accordingly, when the collector-emitter voltage Vce is applied, the voltage of the field regions 56 is less likely to reach the breakdown voltage (BV). As a result, the semiconductor device 10 becomes more resistant to breakdown. In other words, the electrical characteristics of the semiconductor device 10 are improved. (1-2) The field regions 56 include the outermost field region 56D located closest to the peripheral edge of the chip 12. The field regions 56 include the inner field regions 56A to 56C located closer to the well region 54 than the outermost field region 56D is. The cathode region 110 is formed to face the inner field regions 56A to 56C in the thickness direction of the chip 12.

In the field regions 56, the peak value of the electric field intensity is likely to be higher in the inner field regions 56A to 56C than in the outermost field region 56D. In this regard, the cathode region 110 is formed to face the inner field regions 56A to 56C in the thickness direction of the chip 12. This mitigates electric field concentration in the inner field regions 56A to 56C, in which the voltage of the field regions 56 is relatively likely to reach the breakdown voltage. As a result, the semiconductor device 10 becomes more resistant to breakdown. In other words, the electrical characteristics of the semiconductor device 10 are improved.
(1-3) The chip 12 includes the channel stop region 58 formed in a surface region of the first main surface 12A in the peripheral region 18 and separated from the field regions 56 toward the peripheral edge of the chip 12. The cathode region 110 is formed to face a position separated from the channel stop region 58 toward the field regions 56 in the thickness direction of the chip 12.

With this configuration, the electric field intensity is lower in the channel stop region 58 than in the field regions 56. In other words, the channel stop region 58 is less likely to reach the breakdown voltage than the field regions 56. In this case, the cathode region 110 is formed to face the field regions 56, which relatively easily reach the breakdown voltage, in the thickness direction of the chip 12. This mitigates electric field concentration effectively.
(1-4) In plan view, the cathode region 110 has a loop shape that surrounds the well region 54.

With this configuration, the cathode region 110 faces the field regions 56 in the thickness direction of the chip 12 along the entire perimeter of the field regions 56. This mitigates electric field concentration along the entire perimeter of the field regions 56.
(1-5) The chip 12 includes the collector region 24 of the first conductivity type formed in a surface region of the second main surface 12B. The cathode region 110 has the second conductivity type impurity concentration (n-type impurity concentration) that is higher than the first conductivity type impurity concentration (p-type impurity concentration) of the collector region 24. With this configuration, the cathode region 110 mitigates electric field concentration in the field regions 56 further effectively.
(1-6) The field regions 56 include a specific field region in which an electric field having a maximum intensity occurs when the collector-emitter voltage Vce is applied. The cathode region 110 is formed to face the specific field region in the thickness direction of the chip 12.

With this configuration, the cathode region 110 is formed to face, in the thickness direction of the chip 12, the specific field region that is set by, for example, adjusting the spacing of the field regions at the design stage. This ensures that the cathode region 110 is formed to face the field region 56, in which an electric field having the maximum intensity occurs, in the thickness direction. As a result, electric field concentration is mitigated effectively in the field region 56 (specific field region), in which the voltage is most likely to reach the breakdown voltage.
(1-7) The cathode region 110 faces either one of the inner field regions 56A and 56B in the thickness direction of the chip 12. The inner field regions 56A and 56B are ones of the inner field regions 56A to 56C of the field regions 56 located relatively close to the well region 54.

With this configuration, a current path between the cathode region 110 and the well region 54 is relatively short, such that the forward current IF of the diode 112 is increased. In a case in which the cathode region 110 faces the inner field region 56A, which is located closer to the well region 54 than the inner field region 56B is, in the thickness direction of the chip 12, the forward current IF is increased further effectively.
(1-8) The cathode region 110 is formed to face a corresponding one of the field regions 56 in the thickness direction of the chip 12 along the entire perimeter of the corresponding one of the field regions 56. This configuration mitigates electric field concentration in the field region 56 along the entire perimeter of the field region 56.

### Second Embodiment

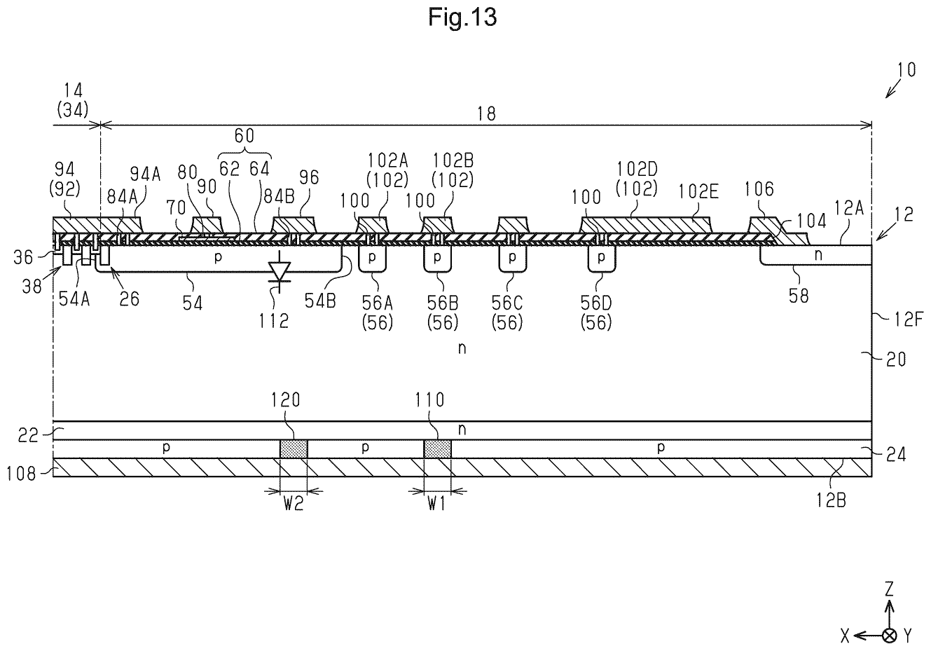

A semiconductor device 10 in accordance with a second embodiment will now be described with reference to FIGS. 13 to 20. The semiconductor device 10 of the second embodiment differs from the semiconductor device 10 of the first embodiment mainly in that an inner cathode region 120 is added. Hereinafter, the same reference characters are given to those components that are the same as the corresponding components of the semiconductor device 10 in the first embodiment. Such components will not be described in detail.

### Configuration and Position of Inner Cathode Region

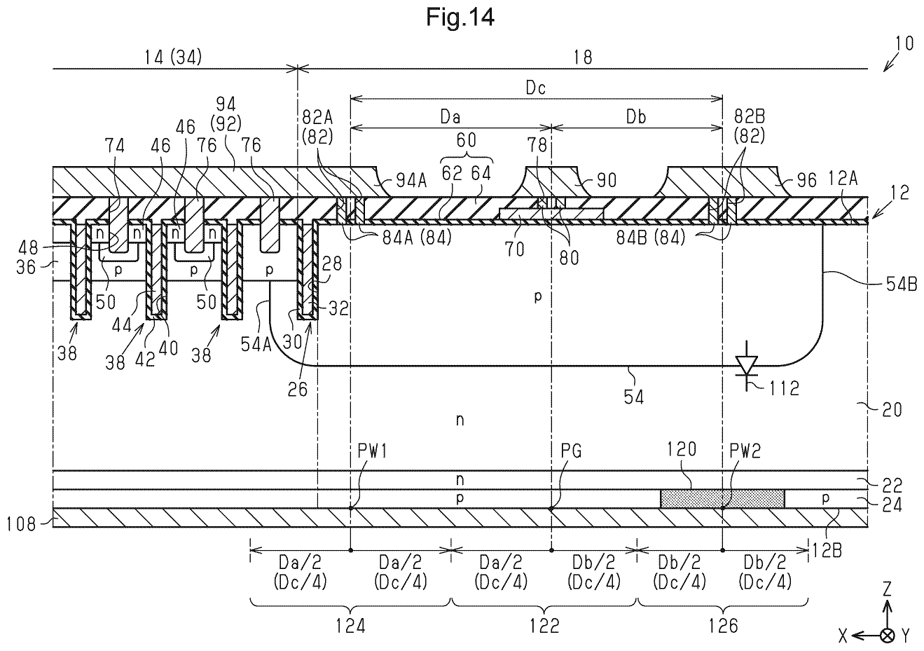

The configuration and position of the inner cathode region 120 will now be described with reference to FIGS. 13 and 14. FIGS. 13 and 14 are schematic cross-sectional views of the peripheral region 18 and part of the IGBT region 14. The cross-sectional views of FIGS. 13 and 14 are taken at the same position as FIG. 8. FIG. 14 is an enlarged view of the well region 54 and its periphery shown in FIG. 13.

As shown in FIG. 13, the semiconductor device 10 in accordance with the second embodiment includes an n-type inner cathode region 120 formed in a surface region of the second main surface 12B in the peripheral region 18. The inner cathode region 120 has an n-type impurity concentration that is higher than the p-type impurity concentration of the collector region 24. In the same manner as the cathode region 110, the inner cathode region 120 is a region in which the conductivity type of the collector region 24 is changed from p-type to n-type. Preferably, the inner cathode region 120 has a higher n-type impurity concentration than the drift region 20 (buffer region 22). In an example, the n-type impurity concentration of the inner cathode region 120 is equal to the n-type impurity concentration of the cathode region 110. The relationship of the n-type impurity concentration between the inner cathode region 120 and the cathode region 110 may be changed. In an example, the n-type impurity concentration of the inner cathode region 120 may be higher than the n-type impurity concentration of the cathode region 110. In an example, the n-type impurity concentration of the inner cathode region 120 may be lower than the n-type impurity concentration of the cathode region 110.

The inner cathode region 120 forms a layer that extends along the second main surface 12B. The inner cathode region 120 is exposed from the second main surface 12B. The inner cathode region 120 extends through the collector region 24 to be connected to the buffer region 22. The inner cathode region 120 is electrically connected to the collector electrode 108. The inner cathode region 120 is in ohmic contact with the collector electrode 108.

The inner cathode region 120 is separated from the cathode region 110 toward the IGBT region 14. More specifically, the inner cathode region 120 is formed to face the well region 54 in the thickness direction of the chip 12. In a surface region of the second main surface 12B, the inner cathode region 120 faces the cathode region 110 with part of the collector region 24 located in between. The inner cathode region 120 forms the diode 112 together with the cathode region 110 and the well region 54.

The inner cathode region 120 may have an endless or open-ended strip shape that surrounds the IGBT region 14 in plan view. In an example, the inner cathode region 120 has a loop shape (in the second embodiment, a quadrangular loop with rounded corners) that surrounds the IGBT region 14. The cathode region 110 surrounds the inner cathode region 120 in plan view.

The inner cathode region 120 is formed so that the well region 54 has a portion that faces the inner cathode region 120 in the thickness direction of the chip 12 and a portion that faces the collector region 24 in the thickness direction of the chip 12. In other words, the inner cathode region 120 is formed to be narrower than the well region 54 so as not to face the entire well region 54 in the thickness direction of the chip 12. The width W2 of the inner cathode region 120 may be in a range from 5 μm to 90 μm, inclusive. The width W2 of the inner cathode region 120 may be in a range from 10 μm to 40 μm, inclusive. The width W2 of the inner cathode region 120 may be defined by a dimension orthogonal to the direction in which the inner cathode region 120 extends in plan view.

The inner cathode region 120 is separated from the base region 36 toward the peripheral edge of the chip 12 so as not to face at least the base region 36 in the thickness direction of the chip 12. The inner cathode region 120 is separated from the trench gate structures 38 toward the peripheral edge of the chip 12 so as not to face the trench gate structures 38 in the thickness direction of the chip 12. The inner cathode region 120 is separated from the trench isolation structure 26 toward the peripheral edge of the chip 12 so as not to face the trench isolation structure 26 in the thickness direction of the chip 12.

Accordingly, the inner cathode region 120 is separated from the IGBT region 14 toward the peripheral edge of the chip 12 so as not to face the IGBT region 14 in the thickness direction of the chip 12. In other words, the inner cathode region 120 is formed only in the peripheral region 18 and is absent within the IGBT region 14. This reduces electrical interference between the IGBT region 14 and the diode 112.

In an example, a ratio of a surface area of the inner cathode region 120 to a surface area of the second main surface 12B is in a range of 0.1% to 10%, inclusive. In an example, the ratio of the surface area of the inner cathode region 120 to the surface area of the second main surface 12B may be in at least one of a range of 0.1% to 1%, inclusive, 1% to 2%, inclusive, 2% to 4%, inclusive, 4% to 6%, inclusive, 6% to 8%, inclusive, and 8% to 10%, inclusive.

### Method for Setting Position of Inner Cathode Region

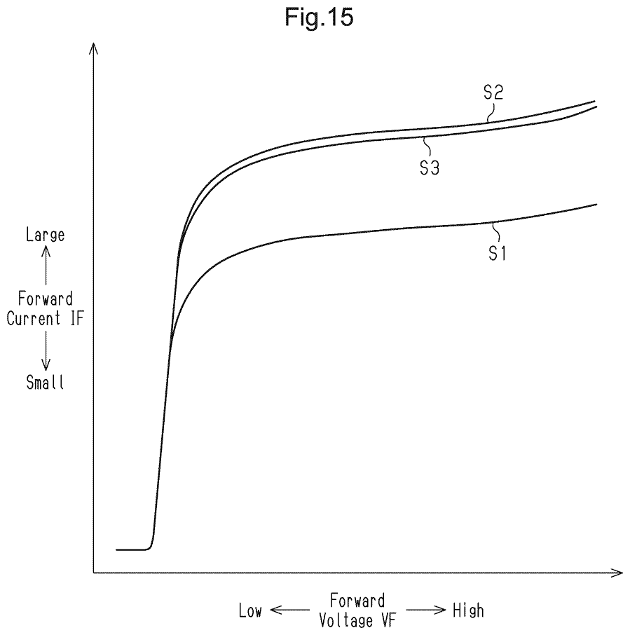

A method for setting the position of the inner cathode region 120 will now be described with reference to FIGS. 15 to 17. In the description hereafter, components of the semiconductor device 10 will be denoted by the reference characters assigned to the components of the semiconductor device 10 shown in FIGS. 13 and 14.

When a forward voltage VF of the diode 112 is applied between the emitter electrode 92 and the collector electrode 108, a forward current IF flows through the diode 112. For example, the forward current IF flows from the first well connection electrode 84A and the second well connection electrode 84B to the inner cathode region 120. The electrical characteristic of the diode 112 during forward operation varies in accordance with the position of the inner cathode region 120.

FIG. 15 shows the forward current IF relative to the forward voltage VF, in accordance with various positions of the inner cathode region 120. The vertical axis of the graph shown in FIG. 15 indicates the forward current IF (A). The horizontal axis of the graph shown in FIG. 15 indicates the forward voltage VF (V). FIG. 15 shows first characteristic S1, second characteristic S2, and third characteristic S3. The first characteristic S1 corresponds to a case in which the inner cathode region 120 is located at the gate reference position PG. The second characteristic S2 corresponds to a case in which the inner cathode region 120 is located at the first well reference position PW1. The third characteristic S3 corresponds to a case in which the inner cathode region 120 is located at the second well reference position PW2.

The gate reference position PG is located directly below the center of the gate line electrode 90. In an example, the gate reference position PG is located directly below the center of the gate line wiring 70. In other words, the gate reference position PG faces the gate line electrode 90 in the thickness direction of the chip 12. Further, the gate reference position PG faces the gate line wiring 70 in the thickness direction of the chip 12.

As shown in FIG. 15, the forward current IF corresponding to the second characteristic S2 is greater than the forward current IF corresponding to the first characteristic S1. Further, the forward current IF corresponding to the third characteristic S3 is greater than the forward current IF corresponding to the first characteristic S1. Thus, it is preferred that the inner cathode region 120 is formed to avoid the gate reference position PG, so as to avoid formation of a current bypass. Preferably, the inner cathode region 120 is formed at one or both of the first well reference position PW1 and the second well reference position PW2.

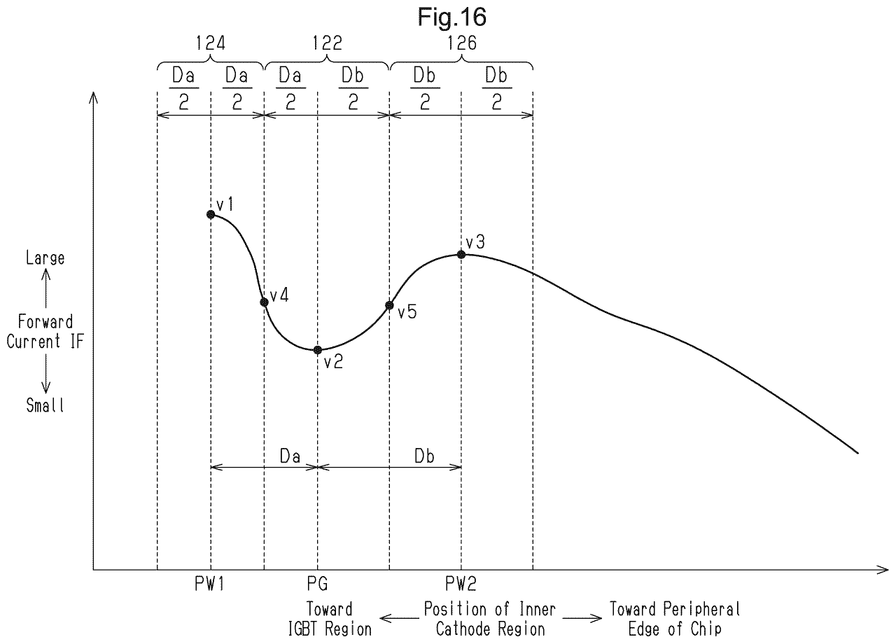

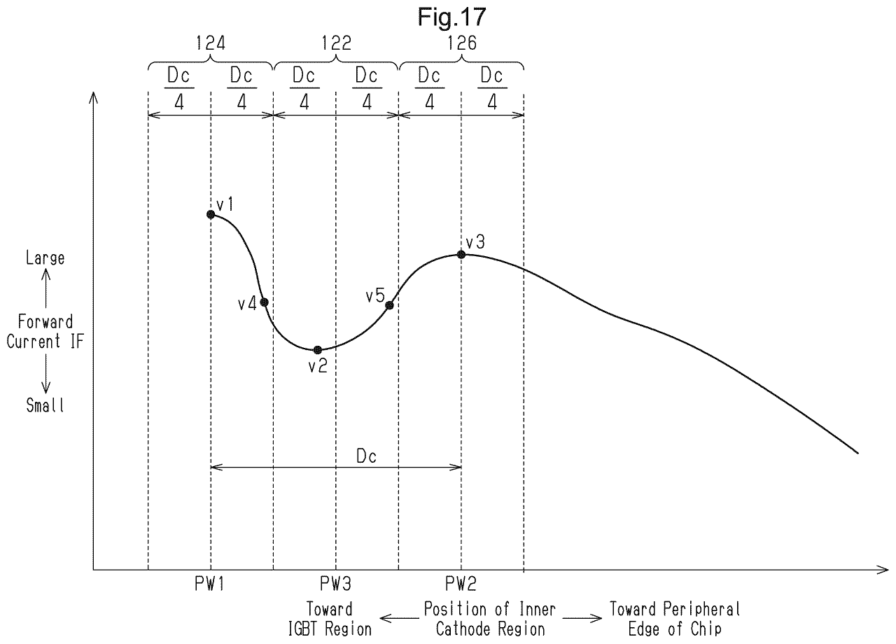

FIGS. 16 and 17 are graphs of the forward current IF relative to the position of the inner cathode region 120. The horizontal axes in FIGS. 16 and 17 indicate the position of the inner cathode region 120. The vertical axes in FIGS. 16 and 17 indicate the magnitude of the forward current IF. The graphs shown in FIGS. 16 and 17 have the same graph format as the graph shown in FIG. 12. In the first embodiment, the description focused on the region extending from the second well reference position PW2 toward the peripheral edge of the chip 12. In the second embodiment, description will focus on a region extending from the first well reference position PW1 to the second well reference position PW2.

As shown in FIGS. 16 and 17, the forward current IF has a first local maximum value v1 in a case in which the inner cathode region 120 is located at the first well reference position PW1. The forward current IF has a local minimum value v2 in a case in which the inner cathode region 120 is located at the gate reference position PG. The forward current IF has a second local maximum value v3 in a case in which the inner cathode region 120 is located at the second well reference position PW2.

In a case in which the inner cathode region 120 is located proximate to a position directly below a midpoint between the first well reference position PW1 and the gate reference position PG, the forward current IF has a value proximate to the middle value of the first local maximum value v1 and the local minimum value v2. The value proximate to the middle value of the first local maximum value v1 and the local minimum value v2 is also a value proximate to a first inflection point v4 between the first local maximum value v1 and the local minimum value v2.

In a case in which the inner cathode region 120 is located proximate to a position directly below a midpoint between the gate reference position PG and the second well reference position PW2, the forward current IF has a value proximate to the middle value of the local minimum value v2 and the second local maximum value v3. The value proximate to the middle value of the local minimum value v2 and the second local maximum value v3 is also a value proximate to a second inflection point v5 between the local minimum value v2 and the second local maximum value v3.

Thus, it is preferred that a prohibition range 122 is set on the second main surface 12B to prohibit formation of the inner cathode region 120 proximate to the gate reference position PG. Further, it is preferred that a first permission range 124 is set on the second main surface 12B to permit formation of part of or entirety of the inner cathode region 120 proximate to the first well reference position PW1. Furthermore, it is preferred that a second permission range 126 is set on the second main surface 12B to permit formation of part of or the entirety of the inner cathode region 120 proximate to the second well reference position PW2.

Setting examples of the prohibition range 122, the first permission range 124, and the second permission range 126 will now be described. FIG. 16 shows a first setting example, and FIG. 17 shows a second setting example.

### First Setting Example

In the first setting example, the prohibition range 122, the first permission range 124, and the second permission range 126 are set based on the distance between the first well reference position PW1 and the gate reference position PG and the distance between the second well reference position PW2 and the gate reference position PG.

As shown in FIG. 16, in a case in which the inner cathode region 120 is formed in a portion located relatively close to the first well reference position PW1, the prohibition range 122 and the first permission range 124 may be set based on a first reference distance Da between the first well reference position PW1 and the gate reference position PG. The first reference distance Da is an example of a “reference distance between the center of the gate electrode and the well connection electrode.”

In this case, the prohibition range 122 is set to a range that does not exceed one-half of the first reference distance Da from the gate reference position PG. The prohibition range 122 is set to extend from the first well reference position PW1 toward the IGBT region 14. In this case, the inner cathode region 120 is distanced from the gate reference position PG toward the first well reference position PW1 by at least one-half of the first reference distance Da. In other words, the inner cathode region 120 is absent within a range that does not exceed one-half of the first reference distance Da from the gate reference position PG toward the first well reference position PW1.

The first permission range 124 is set to a range that does not exceed one-half of the first reference distance Da from the first well reference position PW1. The first permission range 124 is set to extend from the first well reference position PW1 toward both the IGBT region 14 and the gate reference position PG. In this case, at least part of the inner cathode region 120 is located within one-half of the first reference distance Da from the first well reference position PW1. In other words, the inner cathode region 120 includes a portion located in a range that does not exceed one-half of the first reference distance Da from the first well reference position PW1, which is located directly below the first well connection electrode 84A.

In a case in which the inner cathode region 120 is formed in a portion located relatively close to the second well reference position PW2, the prohibition range 122 and the second permission range 126 are set based on a second reference distance Db between the second well reference position PW2 and the gate reference position PG. The second reference distance Db is an example of a “reference distance between the center of the gate electrode and the well connection electrode.”

In this case, the prohibition range 122 is set to a range that does not exceed one-half of the second reference distance Db from the gate reference position PG. The prohibition range 122 is set to extend from the gate reference position PG toward the second well reference position PW2. In this case, the inner cathode region 120 is distanced from the gate reference position PG toward the second well reference position PW2 by at least one-half of the second reference distance Db. In other words, the inner cathode region 120 is absent within a range that does not exceed one-half of the second reference distance Db from the gate reference position PG toward the second well reference position PW2.

The second permission range 126 is set to a range that does not exceed one-half of the second reference distance Db from the second well reference position PW2. The second permission range 126 is set to extend from the second well reference position PW2 toward both the peripheral edge of the chip 12 and the gate reference position PG. In this case, at least part of the inner cathode region 120 is located within one-half of the second reference distance Db from the second well reference position PW2. In other words, the inner cathode region 120 includes a portion located in a range that does not exceed one-half of the second reference distance Db from the second well reference position PW2, which is located directly below the second well connection electrode 84B.

In a case in which the inner cathode region 120 is formed in both a portion located relatively close to the first well reference position PW1 and a portion located relatively close to the second well reference position PW2, the prohibition range 122 is set to both a range that does not exceed one-half of the first reference distance Da from the gate reference position PG toward the first well reference position PW1 and a range that does not exceed one-half of the second reference distance Db from the gate reference position PG toward the second well connection electrode 84B.

The first permission range 124 is set to a range that does not exceed one-half of the first reference distance Da from the first well reference position PW1. The first permission range 124 is set to extend from the first well reference position PW1 toward both the IGBT region 14 and the gate reference position PG. The second permission range 126 is set to a range that does not exceed one-half of the second reference distance Db from the second well reference position PW2. The second permission range 126 is set to extend from the second well reference position PW2 toward both the peripheral edge of the chip 12 and the gate reference position PG.

The first reference distance Da may be in a range from 1 μm to 50 μm, inclusive. The first reference distance Da may be set to a value included in any one of the following ranges: a range of 1 μm to 5 μm, inclusive, a range of 5 μm to 10 μm, inclusive, a range of 10 μm to 15 μm, inclusive, a range of 15 μm to 20 μm, inclusive, a range of 20 μm to 25 μm, inclusive, a range of 25 μm to 30 μm, inclusive, a range of 30 μm to 35 μm, inclusive, a range of 35 μm to 40 μm, inclusive, a range of 40 μm to 45 μm, inclusive, or a range of 45 μm to 50 μm, inclusive. Preferably, the first reference distance Da is in a range of 10 μm to 30 μm, inclusive. Further preferably, the first reference distance Da is in a range of 10 μm to 20 μm, inclusive.

The second reference distance Db may be less than the first reference distance Da or greater than or equal to the first reference distance Da. In an example, the second reference distance Db is greater than the first reference distance Da. The second reference distance Db may be in a range of 1 μm to 100 μm, inclusive. The second reference distance Db may be set to a value included in any one of a range of 1 μm to 5 μm, inclusive, a range of 5 μm to 10 μm, inclusive, a range of 10 μm to 20 μm, inclusive, a range of 20 μm to 30 μm, inclusive, a range of 30 μm to 40 μm, inclusive, a range of 40 μm to 50 μm, inclusive, a range of 50 μm to 60 μm, inclusive, a range of 60 μm to 70 μm, inclusive, a range of 70 μm to 80 μm, inclusive, a range of 80 μm to 90 μm, inclusive, or a range of 90 μm to 100 μm, inclusive. Preferably, the second reference distance Db is in a range of 10 μm to 60 μm, inclusive. Further preferably, the second reference distance Db is in a range of 20 μm to 40 μm, inclusive.

### Second Setting Example

In the second setting example, the prohibition range 122, the first permission range 124, and the second permission range 126 are set based on the distance between the first well reference position PW1 and the second well reference position PW2. As shown in FIG. 17, in a case in which the inner cathode region 120 is located at a midpoint reference position PW3, which is directly below a midpoint between the first well reference position PW1 and the second well reference position PW2, the forward current IF has a value proximate to the local minimum value v2.

In a case in which the inner cathode region 120 is located proximate to a position directly below a midpoint between the first well reference position PW1 and the midpoint reference position PW3, the forward current IF has a value proximate to the middle value of the first local maximum value v1 and the local minimum value v2 (value proximate to first inflection point v4). In a case in which the inner cathode region 120 is located proximate to a position directly below a midpoint between the second well reference position PW2 and the midpoint reference position PW3, the forward current IF has a value proximate to the middle value of the second local maximum value v3 and the local minimum value v2 (value proximate to second inflection point v5).

Thus, the prohibition range 122, the first permission range 124, and the second permission range 126 may be set based on a third reference distance Dc between the first well reference position PW1 and the second well reference position PW2. The third reference distance Dc is a total sum (Dc=Da+Db) of the first reference distance Da and the second reference distance Db shown in FIG. 16. In other words, in the second setting example, the prohibition range 122, the first permission range 124, and the second permission range 126 are set based on the third reference distance Dc without using the first reference distance Da or the second reference distance Db. The third reference distance Dc is an example of a “reference distance between the first well connection electrode and the second well connection electrode.”

In this case, the prohibition range 122 may be set to a range that does not exceed one-quarter of the third reference distance Dc from the midpoint reference position PW3, which is located directly below the midpoint between the first well reference position PW1 and the second well reference position PW2. In a case in which the inner cathode region 120 is formed in a portion located relatively close to the first well reference position PW1, the prohibition range 122 is set to extend from the midpoint reference position PW3 toward the first well reference position PW1. In a case in which the inner cathode region 120 is formed in a portion located relatively close to the second well reference position PW2, the prohibition range 122 is set to extend from the midpoint reference position PW3 toward the second well reference position PW2.

The first permission range 124 is set to a range that does not exceed one-quarter of the third reference distance Dc from the first well reference position PW1. The first permission range 124 is set to extend from the first well reference position PW1 toward both the IGBT region 14 and the gate reference position PG. The second permission range 126 is set to a range that does not exceed one-quarter of the third reference distance Dc from the second well reference position PW2. The second permission range 126 is set to extend from the second well reference position PW2 toward both the IGBT region 14 and the gate reference position PG.

As shown in FIG. 17, the inner cathode region 120 is separated from the midpoint reference position PW3. Preferably, the inner cathode region 120 is formed outside the prohibition range 122. More specifically, it is preferred that the inner cathode region 120 is absent within a range that does not exceed one-quarter of the third reference distance Dc from the midpoint reference position PW3.

The inner cathode region 120 may be formed in a portion located between the first well reference position PW1 and the midpoint reference position PW3. In this case, it is preferred that the inner cathode region 120 is partially or entirely located within the first permission range 124. In other words, it is preferred that the inner cathode region 120 is absent within a range that does not exceed one-quarter of the third reference distance Dc from the midpoint reference position PW3 toward the first well connection electrode 84A. Further, it is preferred that the inner cathode region 120 includes a portion located in a range that does not exceed one-quarter of the third reference distance Dc from the first well reference position PW1 toward the midpoint reference position PW3. In this case, it is preferred that the inner cathode region 120 is located at the first well reference position PW1. In other words, it is preferred that the inner cathode region 120 faces the first well connection electrode 84A in the thickness direction of the chip 12.

Furthermore, the inner cathode region 120 may be formed in a portion located between the second well reference position PW2 and the midpoint reference position PW3. In this case, it is preferred that the inner cathode region 120 is partially or entirely located within the second permission range 126. In other words, it is preferred that the inner cathode region 120 is absent within a range that does not exceed one-quarter of the third reference distance Dc from the midpoint reference position PW3 toward the second well connection electrode 84B. Further, it is preferred that the inner cathode region 120 includes a portion located in a range that does not exceed one-quarter of the third reference distance Dc from the second well reference position PW2 toward the midpoint reference position PW3. In this case, it is preferred that the inner cathode region 120 is located at the second well reference position PW2. In other words, it is preferred that the inner cathode region 120 faces the second well connection electrode 84B in the thickness direction of the chip 12.

### Peak Surge Current IFSM

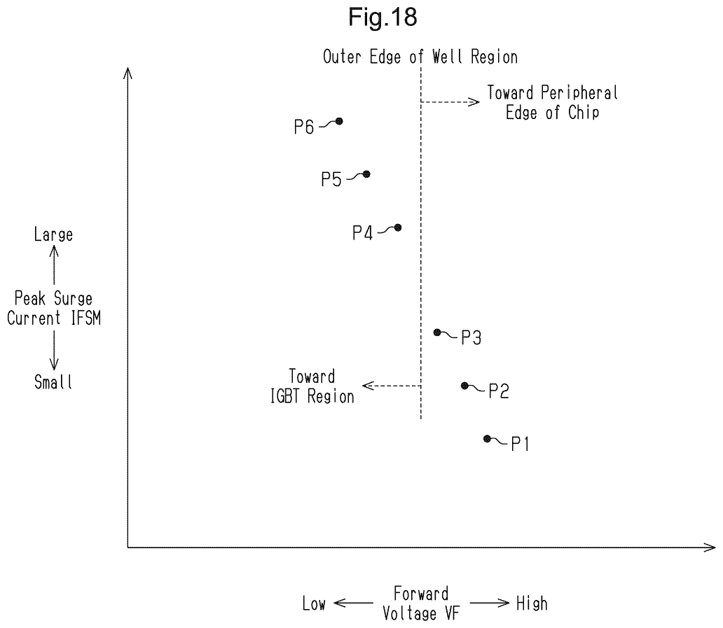

The relationship between the position of the inner cathode region 120 and peak surge current IFSM will now be described with reference to FIG. 18. FIG. 18 is a graph of the peak surge current IFSM relative to the forward voltage VF in accordance with various positions of the inner cathode region 120. The vertical axis in FIG. 18 indicates the peak surge current IFSM (A), and the horizontal axis in FIG. 18 indicates the forward voltage VF (V). The peak surge current IFSM indicates a peak value of a commercial sinusoidal half-wave current (50 Hz or 60 Hz) having one or more cycles within a permissible range that does not cause breakdown.

FIG. 18 shows first to sixth plotted points P1 to P6. The first to third plotted points P1 to P3 represent a characteristic in a case in which the inner cathode region 120 is separated from the well region 54 toward the peripheral edge of the chip 12. The position of the inner cathode region 120 becomes closer to the well region 54 in the order of the first plotted point P1, the second plotted point P2, and the third plotted point P3.

The fourth to sixth plotted points P4 to P6 represent a characteristic in a case in which the inner cathode region 120 is formed to face the well region 54. The position of the inner cathode region 120 becomes closer to the second well reference position PW2 from the outer edge 54B of the well region 54 in the order of the fourth plotted point P4, the fifth plotted point P5, and the sixth plotted point P6. The sixth plotted point P6 represents a characteristic in a case in which the inner cathode region 120 is located at the second well reference position PW2. At the first to sixth plotted points P1 to P6, the width of the inner cathode region 120 is fixed to a constant value (here, 10 μm).

Referring to the first to sixth plotted points P1 to P6, the peak surge currents IFSM at the fourth to sixth plotted points P4 to P6 are greater than the peak surge currents IFSM at the first to third plotted points P1 to P3. Further, the peak surge current IFSM at the sixth plotted point P6 is greater than the peak surge currents IFSM at the first to fifth plotted points P1 to P5. Thus, from the aspect of the peak surge current IFSM, it is preferred that the inner cathode region 120 is located in a region directly below the well region 54. In particular, it is preferred that the inner cathode region 120 is located at the second well reference position PW2.

### Layout of Inner Cathode Region

First to third layout examples of the inner cathode region 120 will now be described.

Referring to FIG. 14, the semiconductor device 10 may include the inner cathode region 120 that is formed in accordance with the first layout example taking into consideration the results shown in FIGS. 15 to 18. The inner cathode region 120 is separated from the gate reference position PG along the second main surface 12B. More specifically, the inner cathode region 120 is separated from the gate reference position PG toward the second well reference position PW2 along the second main surface 12B.

The inner cathode region 120 is located in the second permission range 126 and is absent within the prohibition range 122. In the present example, the first setting example or the second setting example of the prohibition range 122 and the second permission range 126 may be applied. The inner cathode region 120 is located at the second well reference position PW2. The inner cathode region 120 faces the second well connection electrodes 84B in the thickness direction of the chip 12. The inner cathode region 120 is separated from the gate line electrode 90 toward the second well reference position PW2 so as not to face the gate line electrode 90 in the thickness direction of the chip 12.

The inner cathode region 120 is separated from a position directly below the center of the gate line wiring 70 toward the second well reference position PW2. The inner cathode region 120 is separated from positions directly below the gate connection electrodes 80 toward the second well reference position PW2 so as not to face the gate connection electrodes 80 in the thickness direction of the chip 12. The inner cathode region 120 is separated from the gate line wiring 70 toward the second well reference position PW2 so as not to face the gate line wiring 70 in the thickness direction of the chip 12.

The inner cathode region 120 has a smaller width than the emitter line electrode 96. The inner cathode region 120 may have a greater width than the emitter line electrode 96. The inner cathode region 120 is separated from a position directly below the outer edge 54B of the well region 54 toward the second well reference position PW2. In a surface region of the second main surface 12B, the inner cathode region 120 is formed only in a range that faces the well region 54 in the thickness direction of the chip 12.

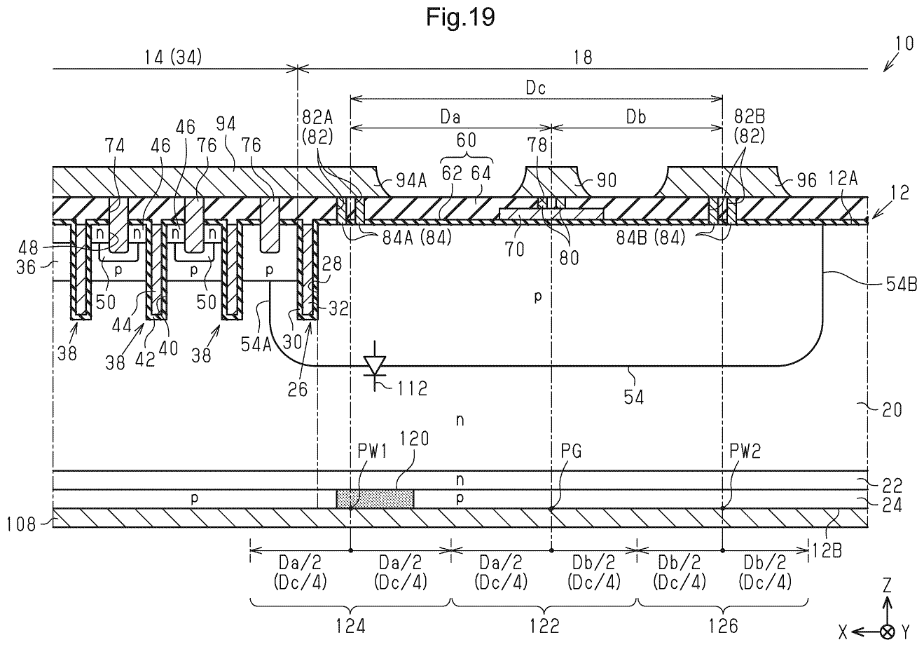

FIG. 19 is a schematic cross-sectional view of the peripheral edge portion of the chip 12, showing the second layout example of the inner cathode region 120.

As shown in FIG. 19, the semiconductor device 10 may include the inner cathode region 120 in accordance with the second layout example. The inner cathode region 120 is separated from the gate reference position PG along the second main surface 12B. More specifically, the inner cathode region 120 is separated from the gate reference position PG toward the first well reference position PW1 (IGBT region 14) along the second main surface 12B.

The inner cathode region 120 is located in the first permission range 124 and is absent within the prohibition range 122. In the present example, the first setting example or the second setting example of the prohibition range 122 and the first permission range 124 may be applied. The inner cathode region 120 is located at the first well reference position PW1. The inner cathode region 120 faces the first well connection electrodes 84A in the thickness direction of the chip 12. The inner cathode region 120 is separated from the gate line electrode 90 toward the first well reference position PW1 so as not to face the gate line electrode 90 in the thickness direction of the chip 12.

The inner cathode region 120 is separated from a position directly below the center of the gate line wiring 70 toward the first well reference position PW1. The inner cathode region 120 is separated from positions directly below the gate connection electrodes 80 toward the first well reference position PW1 so as not to face the gate connection electrodes 80 in the thickness direction of the chip 12. The inner cathode region 120 is separated from the gate line wiring 70 toward the first well reference position PW1 so as not to face the gate line wiring 70 in the thickness direction of the chip 12.

Preferably, regardless of the first permission range 124, the inner cathode region 120 is separated from a position directly below the inner edge 54A of the well region 54 toward the first well reference position PW1. In other words, in a surface region of the second main surface 12B, the inner cathode region 120 is formed only in a range facing the well region 54 in the thickness direction of the chip 12.

In addition, it is preferred that the inner cathode region 120 is separated from the trench gate structures 38 toward the peripheral edge of the chip 12 so as not to face the trench gate structures 38 in the thickness direction of the chip 12. Preferably, the inner cathode region 120 is separated from the trench isolation structure 26 toward the peripheral edge of the chip 12 so as not to face the trench isolation structure 26 in the thickness direction of the chip 12.

In other words, it is preferred that the inner cathode region 120 is separated from the IGBT region 14 toward the peripheral edge of the chip 12 so as not to face the IGBT region 14 in the thickness direction of the chip 12. That is, it is preferred that the inner cathode region 120 is formed only in the peripheral region 18 and is absent within the IGBT region 14. This reduces electrical interference between the IGBT region 14 and the diode 112.

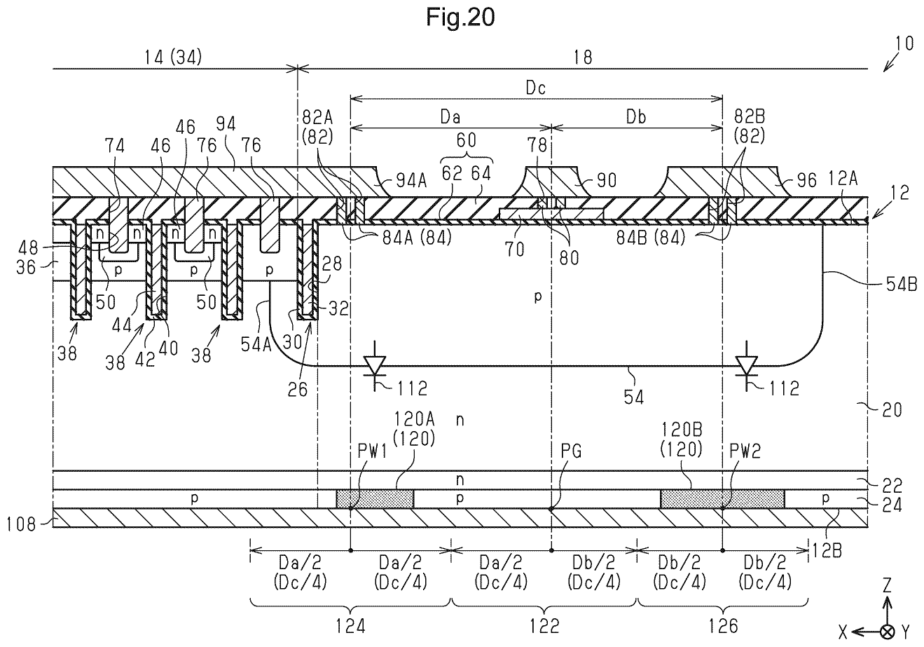

FIG. 20 is a schematic cross-sectional view of the peripheral edge portion of the chip 12, showing the third layout example of the inner cathode region 120.

As shown in FIG. 20, the semiconductor device 10 may include the inner cathode region 120 in accordance with the third layout example. The inner cathode region 120 includes a first inner cathode region 120A located relatively close to the first well reference position PW1, and a second inner cathode region 120B located relatively close to the second well reference position PW2.

The layout of the first inner cathode region 120A is the same as that of the inner cathode region 120 of the second layout example shown in FIG. 19. In an example, the first inner cathode region 120A is separated from the midpoint reference position PW3 toward the first well connection electrode 84A. The layout of the second inner cathode region 120B is the same as that of the inner cathode region 120 of the first layout example shown in FIG. 14. In an example, the second inner cathode region 120B is separated from the midpoint reference position PW3 toward the second well connection electrode 84B. In a surface region of the second main surface 12B, the second inner cathode region 120B faces the first inner cathode region 120A with part of the collector region 24 located in between.

In the first to third layout examples, part of the collector region 24 faces the gate line wiring 70, the gate connection electrodes 80, and the gate line electrode 90 in the thickness direction of the chip 12. Preferably, the part of the collector region 24 faces the entire gate line electrode 90 in the thickness direction of the chip 12. Preferably, the part of the collector region 24 faces the entire gate line wiring 70 in the thickness direction of the chip 12.

### Advantages of the Second Embodiment

The semiconductor device 10 in accordance with the second embodiment has the following advantages in addition to the advantages of the first embodiment.
(2-1) The semiconductor device 10 includes the second conductivity type (n-type) inner cathode region 120 that forms the diode 112 together with the well region 54. The inner cathode region 120 is separated from the gate reference position PG, which is directly below the center of the gate line electrode 90, toward the well connection electrode 84 so as to face the well region 54 in a surface region of the second main surface 12B of the chip 12.

This configuration avoids formation of a current bypass that extends between the well connection electrode 84 and the inner cathode region 120 through a region located directly below the gate line electrode 90. Accordingly, the inner cathode region 120 increases the forward current IF of the diode 112.

In addition, since the inner cathode region 120 increases the forward current IF of the diode 112, the position of the cathode region 110 may be set without taking into consideration the forward current IF of the diode 112. In other words, the freedom of design for the spacing of the field regions 56 may be improved. For example, the spacing of the field regions 56 may be decreased, thereby allowing for a reduction in the size of the semiconductor device 10.
(2-2) The inner cathode region 120 is formed in a surface region of the second main surface 12B in the peripheral region 18 so as to face the well connection electrode 84 in the thickness direction of the chip 12. The inner cathode region 120 forms the diode 112 together with the well region 54.

This configuration allows for formation of a straight current path that connects the well connection electrode 84 and the inner cathode region 120. Accordingly, the forward current IF of the diode 112 is increased during forward operation of the diode 112. As a result, the electrical characteristics of the semiconductor device 10 are improved.
(2-3) The inner cathode region 120 does not face the gate line electrode 90 in the thickness direction of the chip 12.

This configuration further avoids formation of a current bypass that extends through a region directly below the gate line electrode 90.
(2-4) The well connection electrode 84 may include at least one of the first well connection electrode 84A located relatively close to the inner edge 54A of the well region 54 and the second well connection electrode 84B located relatively close to the outer edge 54B of the well region 54.

With this configuration, in a case in which the well connection electrode 84 includes the first well connection electrode 84A, the gate line electrode 90 is separated from the first well connection electrodes 84A toward the outer edge 54B of the well region 54 (peripheral edge of chip 12). In this case, the inner cathode region 120 is separated from a position directly below the center of the gate line electrode 90 toward the inner edge 54A of the well region 54 (IGBT region 14) along the second main surface 12B. This allows for formation of a straight current path that connects the first well connection electrode 84A and the inner cathode region 120.

In this case, it is preferred that the semiconductor device 10 includes the emitter pad electrode 94. The emitter pad electrode 94 is formed on the insulating film 60 and separated from the gate line electrode 90 toward the IGBT region 14, so as to be electrically connected to the well region 54 via the first well connection electrode 84A. The inner cathode region 120 faces the emitter pad electrode 94 in the thickness direction of the chip 12. This allows for formation of a straight current path that connects the emitter pad electrode 94 and the inner cathode region 120.

In a case in which the well connection electrode 84 includes the second well connection electrode 84B, the gate line electrode 90 may be separated from the second well connection electrode 84B toward the inner edge 54A of the well region 54 (IGBT region 14). In this case, the inner cathode region 120 is separated from a position directly below the center of the gate line electrode 90 toward the outer edge 54B of the well region 54 (peripheral edge of the chip 12) along the second main surface 12B. This allows for formation of a straight current path that connects the second well connection electrode 84B and the inner cathode region 120.

In this case, it is preferred that the semiconductor device 10 includes the emitter line electrode 96. The emitter line electrode 96 is formed on the insulating film 60 and separated from the gate line electrode 90 toward the peripheral edge of the chip 12, so as to be electrically connected to the well region 54 via the second well connection electrode 84B. The inner cathode region 120 faces the emitter line electrode 96 in the thickness direction of the chip 12. This allows for formation of a straight current path that connects the emitter line electrode 96 and the inner cathode region 120.
(2-5) The semiconductor device 10 includes the gate line wiring 70 and the gate connection electrode 80. The gate line wiring 70 is formed inside the insulating film 60 so as to face the well region 54 in the thickness direction of the chip 12. The gate connection electrode 80 is embedded in the insulating film 60 to be connected to the gate line wiring 70. In this case, the gate line electrode 90 is electrically connected to the gate line wiring 70 via the gate connection electrode 80. The inner cathode region 120 is separated from a position directly below the center of the gate line wiring 70 along the second main surface 12B. This configuration avoids formation of a current bypass that extends through a region directly below the gate line wiring 70.
(2-6) The inner cathode region 120 does not face the gate connection electrode 80 in the thickness direction of the chip 12. The inner cathode region 120 does not face the gate line wiring 70 in the thickness direction of the chip 12. This configuration further avoids formation of a current bypass that extends through a region directly below the gate line wiring 70.
(2-7) In a surface region of the second main surface 12B, the inner cathode region 120 is formed only in a region that faces the well region 54.

With this configuration, a path of the forward current IF of the diode 112 may be limited within a region located between the well region 54 and the inner cathode region 120. This further minimizes a decrease in the forward current IF. In addition, the peak surge current IFSM may be improved.
(2-8) The inner cathode region 120 is separated from the gate reference position PG, which is directly below the center of the gate line electrode 90, toward the well connection electrode 84 along the second main surface 12B.

This configuration avoids formation of a current bypass that extends between the well connection electrode 84 and the inner cathode region 120 through a region directly below the gate line electrode 90, while shortening the current path between the well connection electrode 84 and the inner cathode region 120. Accordingly, the forward current IF of the diode 112 is increased during forward operation of the diode 112. As a result, the electrical characteristics of the semiconductor device 10 are improved.
(2-9) When the distance between the center of the gate line electrode 90 and the first well connection electrode 84A is referred to as the first reference distance Da, the inner cathode region 120 is absent within a range that does not exceed one-half of the first reference distance Da from the gate reference position PG. That is, the inner cathode region 120 is formed outside the prohibition range 122. This configuration avoids formation of a current bypass that extends through a region directly below the gate line electrode 90. Accordingly, the forward current IF may be increased.
(2-10) When the distance between the center of the gate line electrode 90 and the well connection electrode 84 is referred to as the first reference distance Da, the inner cathode region 120 includes a portion located in a range that does not exceed one-half of the first reference distance Da from the first well reference position PW1, which is directly below the first well connection electrode 84A. In other words, in a case in which the inner cathode region 120 is formed in a portion located relatively close to the first well reference position PW1, the inner cathode region 120 is partially or entirely located in the first permission range 124. With this configuration, the current path between the first well connection electrode 84A and the inner cathode region 120 is shortened, thereby further improving the forward current IF.
(2-11) The inner cathode region 120 is located at the first well reference position PW1.

This configuration allows for formation of a straight current path that connects the first well connection electrode 84A and the inner cathode region 120, thereby further improving the forward current IF.
(2-12) When the distance between the center of the gate line electrode 90 and the second well connection electrode 84B is referred to as the second reference distance Db, the inner cathode region 120 is absent within a range that does not exceed one-half of the second reference distance Db from the gate reference position PG. That is, the inner cathode region 120 is formed outside the prohibition range 122. This configuration avoids formation of a current bypass that extends through a region directly below the gate line electrode 90. Accordingly, the forward current IF may be increased.
(2-13) When the distance between the center of the gate line electrode 90 and the second well connection electrode 84B is referred to as the second reference distance Db, the inner cathode region 120 includes a portion located in a range that does not exceed one-half of the second reference distance Db from the second well reference position PW2, which is directly below the second well connection electrode 84B. In other words, in a case in which the inner cathode region 120 is formed in a portion located relatively close to the second well reference position PW2, the inner cathode region 120 is partially or entirely located in the second permission range 126. With this configuration, the current path between the second well connection electrode 84B and the inner cathode region 120 is shortened, thereby further improving the forward current IF.
(2-14) The inner cathode region 120 is located at the second well reference position PW2.

This configuration allows for formation of a straight current path that connects the second well connection electrode 84B and the inner cathode region 120, thereby further improving the forward current IF.
(2-15) The inner cathode region 120 is separated from the midpoint reference position PW3, which is directly below the midpoint between the first well connection electrode 84A and the second well connection electrode 84B, along the second main surface 12B.

This configuration avoids formation of a current bypass that extends between the first well connection electrode 84A and the second well connection electrode 84B through a region directly below the midpoint. Accordingly, the forward current IF of the diode 112 is increased during forward operation of the diode 112. As a result, the electrical characteristics of the semiconductor device 10 are improved.
(2-16) When the distance between the first well connection electrode 84A and the second well connection electrode 84B is referred to as the third reference distance Dc, the inner cathode region 120 is absent within a range that does not exceed one-quarter of the third reference distance Dc from the midpoint reference position PW3. That is, the inner cathode region 120 is formed outside the prohibition range 122. This configuration further avoids formation of a current bypass that extends through a region directly below the midpoint between the first well connection electrode 84A and the second well connection electrode 84B.
(2-17) The inner cathode region 120 is separated from the midpoint reference position PW3 toward the first well connection electrode 84A.

With this configuration, the current path between the first well connection electrode 84A and the inner cathode region 120 is shortened, thereby improving the forward current IF.
(2-18) When the distance between the first well connection electrode 84A and the second well connection electrode 84B is referred to as the third reference distance Dc, the inner cathode region 120 includes a portion located in a range that does not exceed one-quarter of the third reference distance Dc from the first well reference position PW1, which is directly below the first well connection electrode 84A. In other words, in a case in which the inner cathode region 120 is formed in a portion located relatively close to the first well reference position PW1, the inner cathode region 120 is partially or entirely located in the first permission range 124. With this configuration, the current path between the first well connection electrode 84A and the inner cathode region 120 is shortened, thereby further improving the forward current IF.
(2-19) The inner cathode region 120 includes a portion that overlaps the first well reference position PW1.

This configuration allows for formation of a straight current path that connects the first well connection electrode 84A and the inner cathode region 120, thereby further improving the forward current IF.
(2-20) The inner cathode region 120 is separated from the midpoint reference position PW3 toward the second well connection electrode 84B.

With this configuration, the current path between the second well connection electrode 84B and the inner cathode region 120 is shortened, thereby improving the forward current IF.
(2-21) When the distance between the first well connection electrode 84A and the second well connection electrode 84B is referred to as the third reference distance Dc, the inner cathode region 120 includes a portion located in a range that does not exceed one-quarter of the third reference distance Dc from the second well reference position PW2, which is directly below the second well connection electrode 84B. In other words, in a case in which the inner cathode region 120 is formed in a portion located relatively close to the second well reference position PW2, the inner cathode region 120 is partially or entirely located in the second permission range 126. With this configuration, the current path between the second well connection electrode 84B and the inner cathode region 120 is shortened, thereby further improving the forward current IF.
(2-22) The inner cathode region 120 includes a portion that overlaps the second well reference position PW2.

This configuration allows for formation of a straight current path that connects the second well connection electrode 84B and the inner cathode region 120, thereby further improving the forward current IF.
(2-23) The second conductivity type impurity concentration (n-type impurity concentration) of the inner cathode region 120 is equal to the second conductivity type impurity concentration (n-type impurity concentration) of the cathode region 110.

With this configuration, the inner cathode region 120 and the cathode region 110 may be formed in the same step. Therefore, as compared to when the inner cathode region 120 and the cathode region 110 are formed in different steps, the manufacturing process is simplified.

### Modified Examples

The above-described embodiments may be modified as follows. The modified examples described below may be combined as long as there is no technical contradiction.

In each embodiment, the width W1 of the cathode region 110 may be greater than the width WF of one of the field regions 56. In an example, the width W1 of the cathode region 110 may be greater than the width WF of one of the field regions 56 and less than twice the width WF of the field region 56. In an example, the width W1 of the cathode region 110 may be greater than or equal to two times the width WF of one of the field regions 56.

In each embodiment, the relationship of impurity concentration between the cathode region 110 and the collector region 24 may be changed. In an example, the n-type impurity concentration of the cathode region 110 may be equal to the p-type impurity concentration of the collector region 24. In an example, the n-type impurity concentration of the cathode region 110 may be lower than the p-type impurity concentration of the collector region 24.

In each embodiment, the planar shape of the cathode region 110 may be changed. In an example, the cathode region 110 may have an open-ended loop shape in plan view. In an example, the cathode region 110 may have a linear shape that extends in the X-direction or in the Y-direction in plan view.

In each embodiment, the position of the cathode region 110 may be changed within a portion of the peripheral region 18 located closer to the peripheral edge of the chip 12 than the well region 54 is. In an example, the cathode region 110 may be formed to face the outermost field region 56D of the field regions 56 in the thickness direction of the chip 12. In an example, the cathode region 110 may be formed to face the channel stop region 58 in the thickness direction of the chip 12.

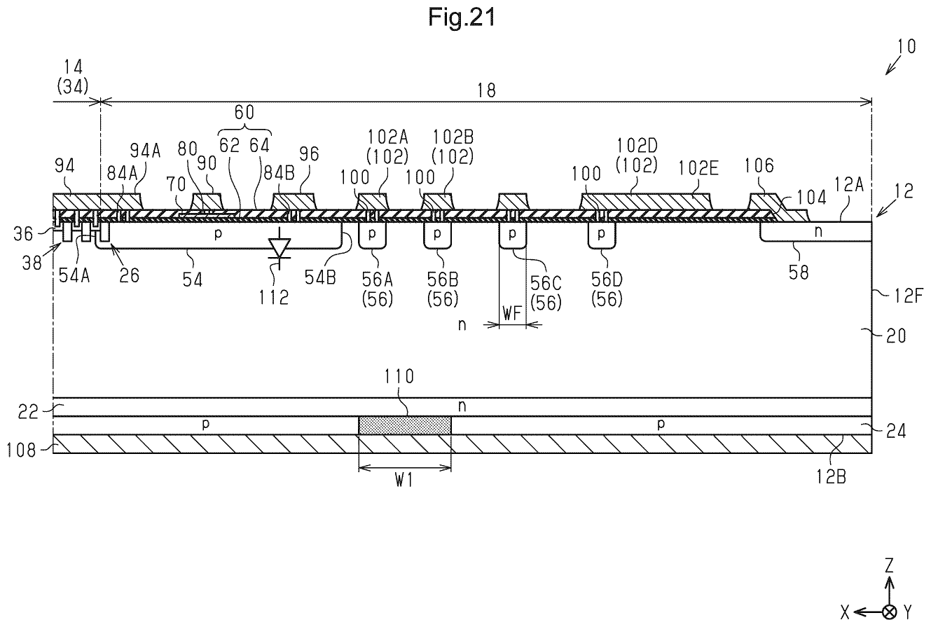

In each embodiment, the cathode region 110 is formed to face one of the field regions 56 in the thickness direction of the chip 12. However, there is no limit to such a configuration. In an example, the cathode region 110 may extend so as to face multiple field regions 56 in the thickness direction of the chip 12. FIG. 21 shows a first example of such a configuration. FIG. 21 is a schematic cross-sectional view of the peripheral edge portion of the chip 12. The cross-sectional view of FIG. 21 is taken at the same position as FIG. 8.

As shown in FIG. 21, the cathode region 110 extends so as to face the inner field regions 56A and 56B of the field regions 56 in the thickness direction of the chip 12. In this case, the width W1 of the cathode region 110 is greater than two times the width WF of one of the field regions 56. In the example shown in FIG. 21, the cathode region 110 is located closer to the well region 54 than the inner field region 56C is. FIG. 21 shows an example in which the electric field intensity is higher in both of the inner field regions 56A and 56B than in the inner field region 56C or the outermost field region 56D. Since the cathode region 110 is formed to face the inner field regions 56A and 56B in the thickness direction of the chip 12, electric field concentration in the inner field regions 56A and 56B is mitigated.

Although not shown in the drawings, in an example in which the electric field intensity is higher in both of the inner field regions 56B and 56C than in the inner field region 56A or the outermost field region 56D, the cathode region 110 may be formed to face the inner field regions 56B and 56C in the thickness direction of the chip 12. This may mitigate electric field concentration in the inner field regions 56B and 56C.

Although not shown in the drawings, the cathode region 110 may extend so as to face, for example, all of the inner field regions 56A to 56C in the thickness direction of the chip 12. This may mitigate electric field concentration in the inner field regions 56A to 56C.

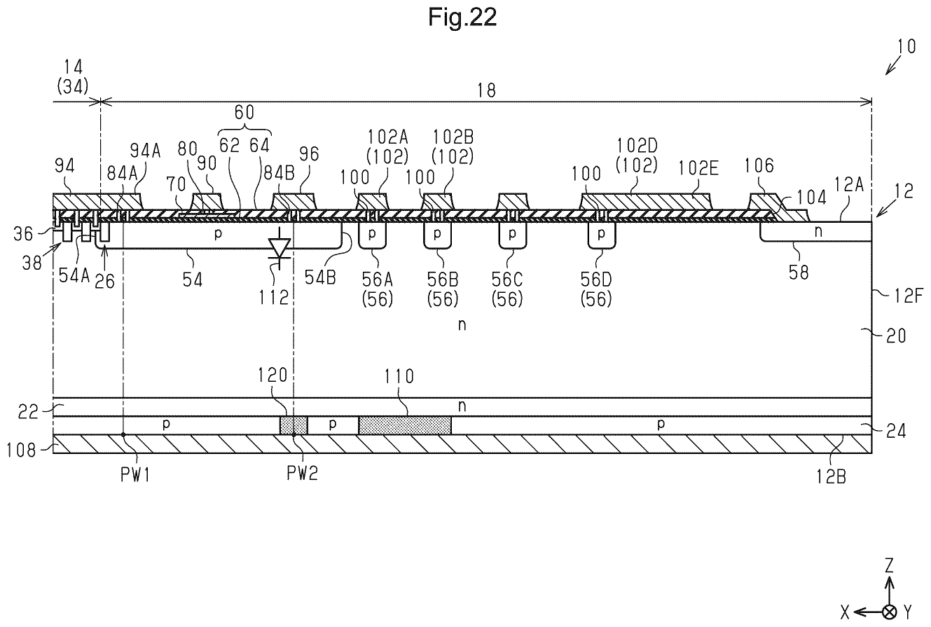

FIG. 22 shows a configuration in which the inner cathode region 120 is added to the example shown in FIG. 21. FIG. 22 is a schematic cross-sectional view of the peripheral edge portion of the chip 12. The cross-sectional view of FIG. 22 is taken at the same position as FIG. 21.

As shown in FIG. 22, the inner cathode region 120 is formed to face the second well connection electrode 84B in the thickness direction of the chip 12. In other words, the inner cathode region 120 is located at the second well reference position PW2. The inner cathode region 120 may be formed to face the first well connection electrode 84A in the thickness direction of the chip 12. That is, the inner cathode region 120 may be located at the first well reference position PW1. The position of the inner cathode region 120 may be the same as that of the second embodiment.

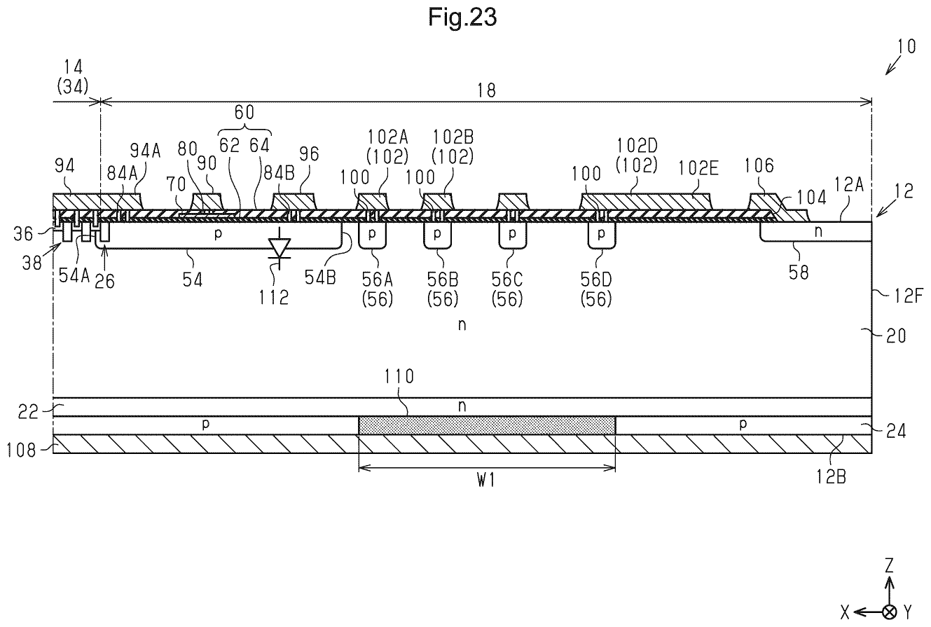

FIG. 23 shows a second example in which the width W1 of the cathode region 110 is changed. FIG. 23 is a schematic cross-sectional view of the peripheral edge portion of the chip 12. The cross-sectional view of FIG. 23 is taken at the same position as FIG. 13.

As shown in FIG. 23, the inner cathode region 120 extends so as to face the entire region of all the field regions 56 in the thickness direction of the chip 12. The inner cathode region 120 is separated from the channel stop region 58 toward the field regions 56 so as not to face the channel stop region 58 in the thickness direction of the chip 12.

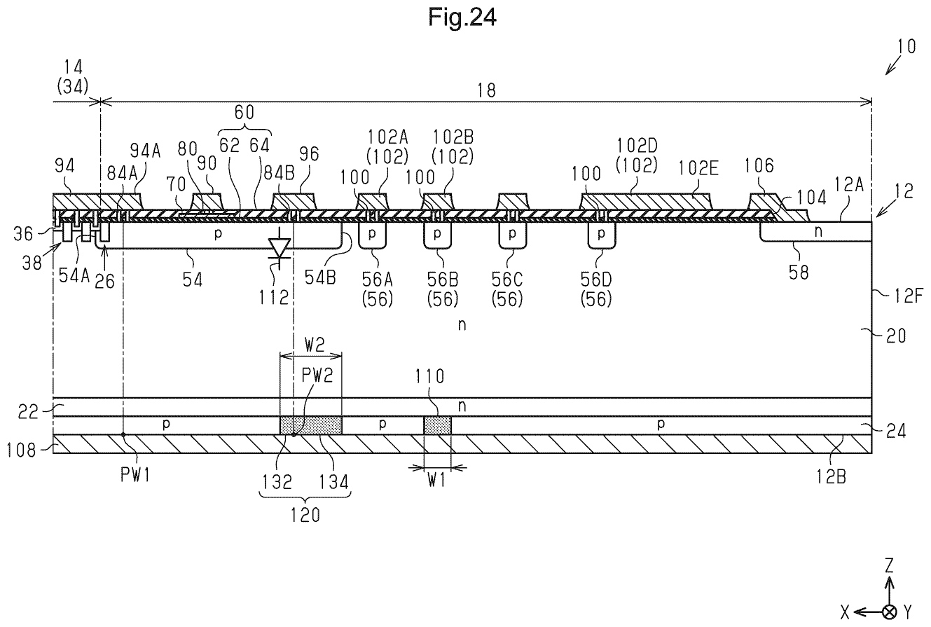

In the second embodiment, the width W2 of the inner cathode region 120 may be changed. FIG. 24 shows a modified example in which the width W2 of the inner cathode region 120 is changed. FIG. 24 is a schematic cross-sectional view of the peripheral edge portion of the chip 12. The cross-sectional view of FIG. 24 is taken at the same position as FIG. 13.

As shown in FIG. 24, the inner cathode region 120 includes a facing portion 132 and a cathode extension 134. The facing portion 132 faces the well region 54 in the thickness direction of the chip 12. The cathode extension 134 extends from the facing portion 132 toward the peripheral edge of the chip 12.

The facing portion 132 is separated from the gate reference position PG toward the second well reference position PW2 along the second main surface 12B. The facing portion 132 is located in the second permission range 126. The facing portion 132 is absent within the prohibition range 122. In the present example, the first setting example or the second setting example of the prohibition range 122 and the second permission range 126 in accordance with the second embodiment may be applied.

The facing portion 132 is located at the second well reference position PW2. The facing portion 132 faces the second well connection electrodes 84B in the thickness direction of the chip 12. The facing portion 132 is separated from the gate line electrode 90 toward the second well reference position PW2 so as not to face the gate line electrode 90 in the thickness direction of the chip 12.

The facing portion 132 is separated from a position directly below the center of the gate line wiring 70 toward the second well reference position PW2. The facing portion 132 is separated from a position directly below the center of the gate connection electrodes 80 toward the second well reference position PW2 so as not to face the gate connection electrodes 80 in the thickness direction of the chip 12. The facing portion 132 is separated from the gate line wiring 70 toward the second well reference position PW2 so as not to face the gate line wiring 70 in the thickness direction of the chip 12.

The cathode extension 134 extends from the facing portion 132 beyond a position directly below the outer edge 54B of the well region 54 toward the peripheral edge of the chip 12. The cathode extension 134 is separated from a position directly below the center of the inner field region 56A toward the well region 54 so as not to face the field regions 56 in the thickness direction of the chip 12. In an example, the width W2 of the inner cathode region 120 may be greater than or equal to the width of the emitter line electrode 96. In an example, the width W2 of the inner cathode region 120 may be less than the width of the emitter line electrode 96. In the example shown in FIG. 24, the width W2 of the inner cathode region 120 is greater than the width W1 of the cathode region 110.

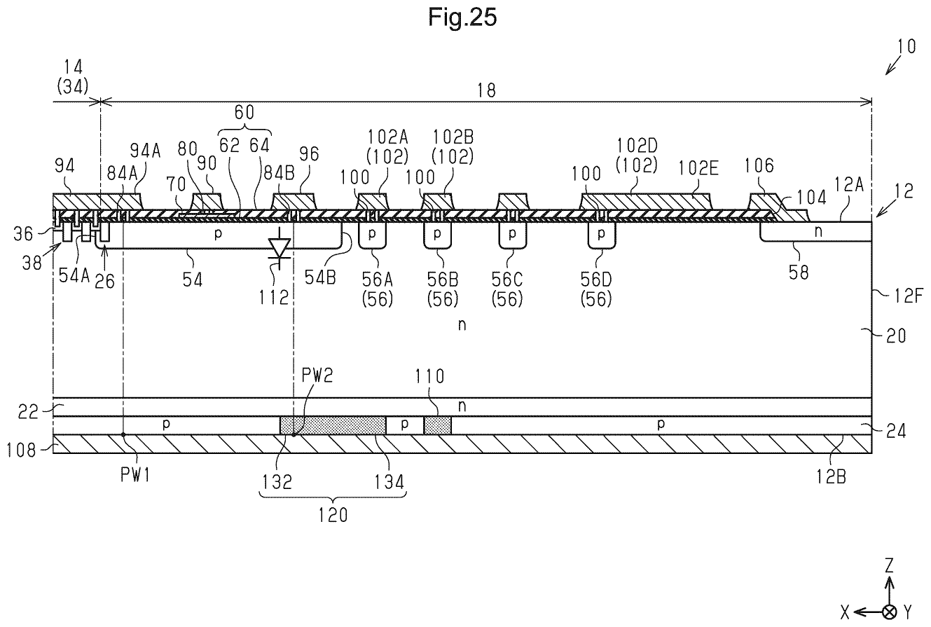

In the modified example shown in FIG. 24, the position of the cathode extension 134 may be changed. FIG. 25 shows a modified example of the cathode extension 134. FIG. 25 is a schematic cross-sectional view of the peripheral edge portion of the chip 12. The cross-sectional view of FIG. 25 is taken at the same position as FIG. 13.

As shown in FIG. 25, the cathode extension 134 may extend so as to face the field regions 56 in the thickness direction of the chip 12. In the example shown in FIG. 25, the cathode extension 134 extends so as to face the inner field region 56A in the thickness direction of the chip 12. The cathode region 110 is separated from the cathode extension 134 toward the peripheral edge of the chip 12. In the example shown in FIG. 25, the cathode region 110 is formed to face the inner field region 56B in the thickness direction of the chip 12.

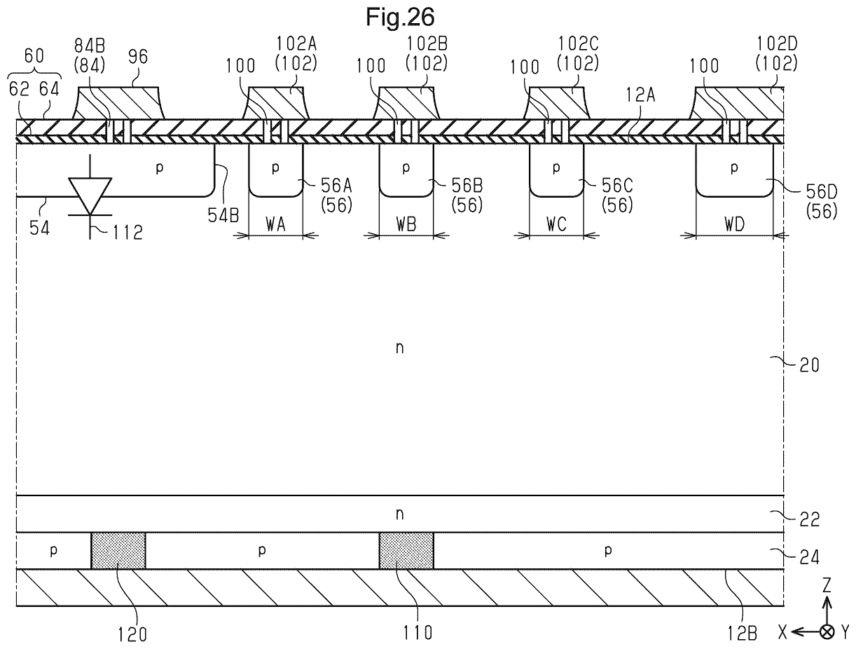

In each embodiment, the field regions 56 may have different widths. FIG. 26 shows a modified example in which the widths of the field regions 56 are varied. FIG. 26 is a schematic cross-sectional view of the peripheral edge portion of the chip 12. The cross-sectional view of FIG. 26 is taken at the same position as FIG. 8.

As shown in FIG. 26, in an example, widths WA to WC of the inner field regions 56A to 56C are each less than width WD of the outermost field region 56D. With this configuration, the electric field intensity is likely to be higher in the inner field regions 56A to 56C that are narrower than in the outermost field region 56D. Accordingly, the cathode region 110 may be formed directly below any one of the inner field regions 56A to 56C to mitigate electric field concentration in the inner field regions 56A to 56C. In particular, it is preferred that the cathode region 110 is formed directly below one of the inner field regions 56A to 56C in which the electric field intensity becomes highest. This mitigates electric field concentration in one of the inner field regions 56A to 56C where dielectric breakdown is most likely to occur. As a result, the breakdown voltage of the semiconductor device 10 is improved.

In an example, the widths WA and WB of the inner field regions 56A and 56B, which are the ones of the inner field regions 56A to 56C located relatively close to the well region 54, may be less than the width WC of the inner field region 56C. With this configuration, the electric field intensity is likely to be higher in the inner field regions 56A and 56B that are narrower than in the inner field region 56C. Accordingly, the cathode region 110 may be formed directly below any one of the inner field regions 56A and 56B to mitigate electric field concentration in the inner field regions 56A and 56B. In another example in which the electric field intensity has substantially the same peak values in the inner field regions 56A and 56B, the peak values of the electric field intensity may be varied by changing the widths of the inner field regions 56A and 56B. For example, when the width WB of the inner field region 56B is decreased to be less than the width WA of the inner field region 56A, the peak value of the electric field intensity in the inner field region 56B becomes higher than the peak value of the electric field intensity in the inner field region 56A. In this case, the cathode region 110 may be formed directly below the inner field region 56B to mitigate electric field concentration in the inner field region 56B, in which the electric field intensity is likely to become relatively high.

In this manner, the peak values of the electric field intensity in the field regions 56 may be varied by adjusting the widths WA to WD of the field regions 56 after the spacing of the field regions 56 has been adjusted. This easily sets the specific field region in which the electric field intensity becomes highest. Then, the cathode region 110 may be formed to face the specific field region in the thickness direction of the chip 12, thereby further mitigating electric field concentration in the specific field region.

In each embodiment, the widths of the field electrodes 102 may be changed individually. In an example, the width of the outermost field electrode 102D of the field electrodes 102 may be equal to the widths of the inner field electrodes 102A to 102C. In an example, the width of at least one of the inner field electrodes 102A to 102C may differ from the widths of the remaining inner field electrodes. In an example, the widths of the inner field electrodes 102A to 102C may be determined in accordance with the widths of the inner field regions 56A to 56C. In an example, in a case in which the width WC of the inner field region 56C is greater than the widths WA and WB of the inner field regions 56A and 56B, the width of the inner field electrode 102C is greater than the widths of the inner field electrodes 102A and 102B.

In each embodiment, the emitter connection electrodes 76 may be integrated with the emitter pad electrode 94 (emitter electrode 92). In other words, the emitter pad electrode 94 may be formed on the insulating film 60 to extend into the emitter openings 74. In this case, multiple portions of the emitter pad electrode 94 located in the emitter openings 74 serve as the emitter connection electrodes 76.

In each embodiment, the gate connection electrodes 80 may be integrated with the gate electrode 86 (gate line electrode 90). In other words, the gate electrode 86 may be formed on the insulating film 60 to extend into the gate openings 78. In this case, multiple portions of the gate electrode 86 located in respective gate openings 78 serve as the gate connection electrodes 80.

In each embodiment, the first well connection electrodes 84A may be integrated with the emitter pad electrode 94 (emitter electrode 92). In other words, the emitter pad electrode 94 may be formed on the insulating film 60 to extend into the first well openings 82A. In this case, multiple portions of the emitter pad electrode 94 located in the first well openings 82A serve as the first well connection electrodes 84A.

In each embodiment, the second well connection electrodes 84B may be integrated with the emitter pad electrode 94 (emitter electrode 92). In other words, the emitter pad electrode 94 may be formed on the insulating film 60 to extend into the second well openings 82B. In this case, multiple portions of the emitter pad electrode 94 located in the second well openings 82B serve as the second well connection electrodes 84B.

In each embodiment, the field connection electrodes 100 may be integrated with the field electrode 102. In other words, the field electrode 102 may be formed on the insulating film 60 to extend into the field openings 98. In this case, multiple portions of the field electrode 102 located in the field openings 98 serve as the field connection electrodes 100.

In each embodiment, the emitter line electrode 96 may be formed only in a region that faces the well region 54 in the thickness direction of the chip 12.

In each embodiment, the width of the gate line electrode 90 may be equal to, or less than, the width of the gate line wiring 70.

In the second embodiment, the relationship between the width W1 of the cathode region 110 and the width W2 of the inner cathode region 120 may be changed. In an example, the width W1 of the cathode region 110 may be greater than the width W2 of the inner cathode region 120. In an example, the width W1 of the cathode region 110 may be less than the width W2 of the inner cathode region 120.

In each embodiment, a range in which the insulating film 60 is formed may be changed. The insulating film 60 may only cover at least the well region 54.

In each embodiment, the chip 12 is not limited to a silicon monocrystalline substrate. In an example, the chip 12 may be a monocrystalline substrate of a wide-bandgap semiconductor. The chip 12 may be, for example, a silicon carbide (SiC) monocrystalline substrate, a GaN monocrystalline substrate, or the like.

In each embodiment, the n-type semiconductor regions may be replaced by a p-type semiconductor region, and the p-type semiconductor regions may be replaced by an n-type semiconductor region. Detailed structures of such a configuration may be obtained by replacing “n-type” with “p-type” and replacing “p-type” with “n-type” in the above description and the accompanying drawings.

Various examples described in this specification may be combined as long as there is no technical contradiction.

In the present disclosure, the term “on” includes the meaning of “above” in addition to the meaning of “on” unless clearly described otherwise in the context. Accordingly, for example, a phrase such as “first element formed on second element” may mean that the first element is directly located on the second element in one embodiment and that the first element is located above the second element without contacting the second element in another embodiment. Therefore, the term “on” does not exclude a structure in which another element is formed between the first element and the second element.

The Z-direction as referred to in this disclosure does not have to be the vertical direction, and does not have to exactly coincide with the vertical direction. Accordingly, in the various structures of the present disclosure, “up” and “down” in the Z-direction as referred to in this specification are not limited to “up” and “down” in the vertical direction. For example, the X-direction or the Y-direction may be the vertical direction.

### CLAUSES

Technical concepts that can be understood from the present disclosure will now be described. Reference characters used in the described embodiment are added to corresponding elements in the clauses to aid understanding without any intention to impose limitations on these elements. The reference characters are given as examples to aid understanding, and are not intended to limit elements to the elements denoted by the reference characters.

### Clause 1

A semiconductor device (10), including:
a chip (12) including a first main surface (12A) and a second main surface (12B) opposite of the first main surface (12A);
a peripheral region (18) located in a peripheral edge portion of the first main surface (12A);
an IGBT region (14) located at an inner side of the peripheral region (18) of the first main surface (12A);
a well region (54) of a first conductivity type (p) formed in a surface region of the first main surface (12A) in the peripheral region (18) to define the IGBT region (14);
field regions (56) of the first conductivity type (p) formed in the surface region of the first main surface (12A) in the peripheral region (18) and separated from the well region (54) toward a peripheral edge of the chip (12), the field regions (56) being spaced apart from each other;
a cathode region (110) of a second conductivity type (n) formed in a surface region of the second main surface (12B) in the peripheral region (18), the cathode region (110) forming a diode (112) together with the well region (54);
an insulating film (60) covering at least the well region (54);
an emitter electrode (92) formed on the insulating film (60) to be electrically connected to the well region (54); and
a collector electrode (108) formed on the second main surface (12B) to be electrically connected to the cathode region (110),
in which the cathode region (110) is located closer to the peripheral edge of the chip (12) than the well region (54) is, and the cathode region (110) is formed to face at least one of the field regions (56) in a thickness direction (Z) of the chip (12).

### Clause 2

The semiconductor device according to clause 1, in which
the field regions (56) include an outermost field region (56D) located closest to the peripheral edge of the chip (12),
the field regions (56) include an inner field region (56A to 56C) located closer to the well region (54) than the outermost field region (56D) is, and
the cathode region (110) is formed to face the inner field region (56A to 56C) in the thickness direction (Z) of the chip (12).

### Clause 3

The semiconductor device according to clause 1 or 2, in which the cathode region (110) is formed to face one of the field regions (56) located relatively close to the well region (54) in the thickness direction (Z) of the chip (12).

### Clause 4

The semiconductor device according to any one of clauses 1 to 3, in which a width (W1) of the cathode region (110) is equal to a width (WF) of one of the field regions (56).

### Clause 5

The semiconductor device according to any one of clauses 1 to 3, in which a width (W1) of the cathode region (110) is greater than a width (WF) of one of the field regions (56) and less than two times the width (WF) of the one of the field regions (56).

### Clause 6

The semiconductor device according to any one of clauses 1 to 3, in which the cathode region (110) extends so as to face the field regions (56) in the thickness direction (Z) of the chip (12).

### Clause 7

The semiconductor device according to any one of clauses 1 to 6, further including a channel stop region (58) formed in the surface region of the first main surface (12A) in the peripheral region (18) and separated from the field regions (56) toward the peripheral edge of the chip (12),
in which the cathode region (110) is formed to face a position separated from the channel stop region (58) toward the field regions (56) in the thickness direction (Z) of the chip (12).

### Clause 8

The semiconductor device according to any one of clauses 1 to 7, in which, as viewed in the thickness direction (Z) of the chip (12), the cathode region (110) has a loop shape surrounding the well region (54).

### Clause 9

The semiconductor device according to any one of clauses 1 to 8, further including a collector region (24) of the first conductivity type (p) formed in a surface region of the second main surface (12B),
in which the cathode region (110) has a second conductivity type impurity concentration that is higher than a first conductivity type impurity concentration of the collector region (24).

### Clause 10

The semiconductor device according to any one of clauses 1 to 9, in which
the field regions (56) include a specific field region in which an electric field having a maximum intensity occurs when a collector-emitter voltage (Vce) is applied, and
the cathode region (110) is formed to face the specific field region in the thickness direction (Z) of the chip (12).

### Clause 11

The semiconductor device according to clause 2, further including:
an inner field electrode (102A to 102C) formed on the insulating film (60) and electrically connected to the inner field region (56A to 56C); and
an outermost field electrode (102D) formed on the insulating film (60) and electrically connected to the outermost field region (56D),
in which a width of the outermost field electrode (102D) is greater than a width of the inner field electrode (102A to 102C).

### Clause 12

The semiconductor device according to clause 2, in which a width (WA to WC) of the inner field region (56A to 56C) is less than a width (WD) of the outermost field region (56D).

### Clause 13

The semiconductor device according to any one of clauses 1 to 12, further including:
a well connection electrode (84) embedded in the insulating film (60) to be connected to the well region (54);
a gate line electrode (90) formed on the insulating film (60) and separated from the well connection electrode (84/84A, 84B) so as to face the well region (54); and
an inner cathode region (120) of the second conductivity type (n) formed in the surface region of the second main surface (12B), the inner cathode region (120) being separated from a gate reference position (PG) toward the well connection electrode (84/84A, 84B) along the second main surface (12B) so as to face the well region (54), the gate reference position (PG) being directly below a center of the gate line electrode (90), the inner cathode region (120) forming a diode (112) together with the well region (54).

### Clause 14

The semiconductor device according to clause 13, in which a distance between the center of the gate line electrode (90) and the well connection electrode (84/84A, 84B) is a reference distance (Da/Db), and the inner cathode region (120) is absent within a range (122) not exceeding one-half of the reference distance (Da/Db) from the gate reference position (PG) toward the well connection electrode (84/84A, 84B).

### Clause 15

The semiconductor device according to clause 13, in which a distance between the center of the gate line electrode (90) and the well connection electrode (84/84A, 84B) is a reference distance (Da/Db), and the inner cathode region (120) includes a portion located in a range not exceeding one-half of the reference distance (Da/Db) from a well reference position (PW1/PW2) located directly below the well connection electrode (84/84A, 84B).

### Clause 16

The semiconductor device according to clause 15, in which the inner cathode region (120) is absent within a range not exceeding one-half of the reference distance (Da/Db) from the gate reference position (PG) toward the well connection electrode (84/84A, 84B).

### Clause 17

The semiconductor device according to any one of clauses 13 to 16, in which the inner cathode region (120) includes a portion facing the well connection electrode (84/84A, 84B) in the thickness direction (Z) of the chip (12).

### Clause 18

The semiconductor device according to any one of clauses 13 to 17, in which the inner cathode region (120) does not face the gate line electrode (90) in the thickness direction (Z) of the chip (12).

### Clause 19

The semiconductor device according to any one of clauses 13 to 18, in which
the gate line electrode (90) is separated from the well connection electrode (84/84B) toward the IGBT region (14), and
the inner cathode region (120) is separated from the gate reference position (PG) toward the well connection electrode (84/84B) along the second main surface (12B).

### Clause 20

The semiconductor device according to clause 19, in which the inner cathode region (120) is formed in the surface region of the second main surface (12B) only in a region facing the well region (54).

### Clause 21

The semiconductor device according to clause 19, in which the inner cathode region (120) includes
a facing portion (132) facing the well region (54) in the thickness direction (Z) of the chip (12), and
a cathode extension (134) extending from the facing portion (132) toward the peripheral edge of the chip (12).

### Clause 22

The semiconductor device according to clause 21, in which the cathode extension (134) is located closer to the well region (54) than the field regions (56) are.

### Clause 23

The semiconductor device according to any one of clauses 19 to 21, further including an emitter line electrode (96) formed on the insulating film (60) to be electrically connected to the well region (54) via the well connection electrode (84/84B).

### Clause 24

The semiconductor device according to any one of clauses 13 to 16, in which
the gate line electrode (90) is separated from the well connection electrode (84/84A) toward the peripheral edge of the chip (12), and
the inner cathode region (120) is separated from the gate reference position (PG) toward the IGBT region (14) along the second main surface (12B).

### Clause 25

The semiconductor device according to clause 24, in which the inner cathode region (120) is formed in the surface region of the second main surface (12B) only in a region facing the well region (54).

### Clause 26

The semiconductor device according to clause 24 or 25, further including an emitter pad electrode (94) formed on the insulating film (60) to be electrically connected to the well region (54) via the well connection electrode (84/84A).

### Clause 27

The semiconductor device according to any one of clauses 13 to 26, further including:
a gate line wiring (70) formed inside the insulating film (60) so as to face the well region (54); and
a gate connection electrode (80) embedded in the insulating film (60) to be connected to the gate line wiring (70),
in which the gate line electrode (90) is electrically connected to the gate line wiring (70) via the gate connection electrode (80).

### Clause 28

The semiconductor device according to clause 27, in which the inner cathode region (120) does not face the gate connection electrode (80) in the thickness direction (Z) of the chip (12).

### Clause 29

The semiconductor device according to clause 27 or 28, in which the inner cathode region (120) does not face the gate line wiring (70) in the thickness direction (Z) of the chip (12).

### Clause 30

The semiconductor device according to any one of clauses 1 to 12, further including:
a first well connection electrode (84A) embedded in the insulating film (60) to be connected to the well region (54);
a second well connection electrode (84B) embedded in the insulating film (60) to be connected to the well region (54), the second well connection electrode (84B) being separated from the first well connection electrode (84A) toward the peripheral edge of the chip (12); and
an inner cathode region (120) of the second conductivity type (n) formed in the surface region of the second main surface (12B), the inner cathode region (120) being separated from a midpoint reference position (PW3) along the second main surface (12B) so as to face the well region (54), the midpoint reference position (PW3) being directly below a midpoint between the first well connection electrode (84A) and the second well connection electrode (84B), the inner cathode region (120) forming a diode (112) together with the well region (54).

### Clause 31

The semiconductor device according to clause 30, in which a distance between the first well connection electrode (84A) and the second well connection electrode (84B) is a reference distance (Dc), and the inner cathode region (120) is absent within a range not exceeding one-quarter of the reference distance (Dc) from the midpoint reference position (PW3).

### Clause 32

The semiconductor device according to clause 30, in which the inner cathode region (120) is separated from the midpoint reference position (PW3) toward the first well connection electrode (84A).

### Clause 33

The semiconductor device according to clause 32, in which a distance between the first well connection electrode (84A) and the second well connection electrode (84B) is a reference distance (Dc), and the inner cathode region (120) is absent within a range not exceeding one-quarter of the reference distance (Dc) from the midpoint reference position (PW3) toward the first well connection electrode (84A).

### Clause 34

The semiconductor device according to clause 32, in which a distance between the first well connection electrode (84A) and the second well connection electrode (84B) is a reference distance (Dc), and the inner cathode region (120) includes a portion located in a range not exceeding one-quarter of the reference distance (Dc) from a first well reference position (PW1) toward the midpoint reference position (PW3), the first well reference position (PW1) being directly below the first well connection electrode (84A).

### Clause 35

The semiconductor device according to clause 34, in which the inner cathode region (120) is absent within a range not exceeding one-quarter of the reference distance (Dc) from the midpoint reference position (PW3) toward the first well connection electrode (84A).

### Clause 36

The semiconductor device according to any one of clauses 32 to 35, in which the inner cathode region (120) faces the first well connection electrode (84A) in the thickness direction (Z) of the chip (12).

### Clause 37

The semiconductor device according to clause 30, in which the inner cathode region (120) is separated from the midpoint reference position (PW3) toward the second well connection electrode (84B).

### Clause 38

The semiconductor device according to clause 37, in which a distance between the first well connection electrode (84A) and the second well connection electrode (84B) is a reference distance (Dc), and the inner cathode region (120) is absent within a range not exceeding one-quarter of the reference distance (Dc) from the midpoint reference position (PW3) toward the second well connection electrode (84B).

### Clause 39

The semiconductor device according to clause 37, in which a distance between the first well connection electrode (84A) and the second well connection electrode (84B) is a reference distance (Dc), and the inner cathode region (120) includes a portion located in a range not exceeding one-quarter of the reference distance (Dc) from a second well reference position (PW2) toward the midpoint reference position (PW3), the second well reference position (PW2) being directly below the second well connection electrode (84B).

### Clause 40

The semiconductor device according to clause 39, in which the inner cathode region (120) is absent within a range not exceeding one-quarter of the reference distance (Dc) from the midpoint reference position (PW3) toward the second well connection electrode (84B).

### Clause 41

The semiconductor device according to any one of clauses 37 to 40, in which the inner cathode region (120) faces the second well connection electrode (84B) in the thickness direction (Z) of the chip (12).

### Clause 42

The semiconductor device according to clause 30, in which the inner cathode region (120) includes
a first inner cathode region (120A) separated from the midpoint reference position (PW3) toward the first well connection electrode (84A), and
a second inner cathode region (120B) separated from the midpoint reference position (PW3) toward the second well connection electrode (84B).

### Clause 43

The semiconductor device according to clause 42, in which a distance between the first well connection electrode (84A) and the second well connection electrode (84B) is a reference distance (Dc), and the first inner cathode region (120A) is absent within a range not exceeding one-quarter of the reference distance (Dc) from the midpoint reference position (PW3) toward the first well connection electrode (84A).

### Clause 44

The semiconductor device according to clause 42, in which a distance between the first well connection electrode (84A) and the second well connection electrode (84B) is a reference distance (Dc), and the first inner cathode region (120A) includes a portion located in a range not exceeding one-quarter of the reference distance (Dc) from a first well reference position (PW1) toward the midpoint reference position (PW3), the first well reference position (PW1) being directly below the first well connection electrode (84A).

### Clause 45

The semiconductor device according to clause 44, in which the first inner cathode region (120A) is absent within a range not exceeding one-quarter of the reference distance (Dc) from the midpoint reference position (PW3) toward the first well connection electrode (84A).

### Clause 46

The semiconductor device according to clause 45, in which the second inner cathode region (120B) is absent within a range not exceeding one-quarter of the reference distance (Dc) from the midpoint reference position (PW3) toward the second well connection electrode (84B).

### Clause 47

The semiconductor device according to clause 45, in which the second inner cathode region (120B) includes a portion located in a range not exceeding one-quarter of the reference distance (Dc) from a second well reference position (PW2) toward the midpoint reference position (PW3), the second well reference position (PW2) being directly below the second well connection electrode (84B).

### Clause 48

The semiconductor device according to clause 47, in which the second inner cathode region (120B) is absent within a range not exceeding one-quarter of the reference distance (Dc) from the midpoint reference position (PW3) toward the second well connection electrode (84B).

### Clause 49

The semiconductor device according to any one of clauses 30 to 48, further including a collector region (24) of the first conductivity type (p) formed in the surface region of the second main surface (12B),
in which the inner cathode region (120) has a second conductivity type impurity concentration that is higher than a first conductivity type impurity concentration of the collector region (24).

### Clause 50

The semiconductor device according to any one of clauses 13 to 49, in which a second conductivity type impurity concentration of the inner cathode region (120) is equal to a second conductivity type impurity concentration of the cathode region (110).

### Clause 51

The semiconductor device according to any one of clauses 13 to 49, in which a second conductivity type impurity concentration of the inner cathode region (120) is higher than a second conductivity type impurity concentration of the cathode region (110).

### Clause 52

The semiconductor device according to any one of clauses 13 to 49, in which a second conductivity type impurity concentration of the inner cathode region (120) is lower than a second conductivity type impurity concentration of the cathode region (110).

### Clause 53

The semiconductor device according to any one of clauses 13 to 52, in which a width (W2) of the inner cathode region (120) is equal to a width (W1) of the cathode region (110).

### Clause 54

The semiconductor device according to any one of clauses 13 to 52, in which a width (W2) of the inner cathode region (120) is greater than a width (W1) of the cathode region (110).

### Clause 55

The semiconductor device according to any one of clauses 13 to 52, in which a width (W2) of the inner cathode region (120) is less than a width (W1) of the cathode region (110).

### Clause 56

The semiconductor device according to any one of clauses 13 to 55, further including a base region (36) of the first conductivity type (p) formed in the surface region of the first main surface (12A) in the IGBT region (14).

### Clause 57

The semiconductor device according to clause 56, in which the inner cathode region (120) does not face the base region (36) in the thickness direction (Z) of the chip (12).

### Clause 58

The semiconductor device according to clause 56 or 57, in which the well region (54) is deeper than the base region (36).

### Clause 59

The semiconductor device according to any one of clauses 56 to 58, in which the well region (54) includes a portion extending out of the peripheral region (18) into the IGBT region (14) and connected to the base region (36).

### Clause 60

The semiconductor device according to any one of clauses 13 to 59, further including a trench gate structure (38) formed in the first main surface (12A) in the IGBT region (14).

### Clause 61

The semiconductor device according to clause 60, in which the inner cathode region (120) does not face the trench gate structure (38) in the thickness direction (Z) of the chip (12).

### Clause 62

The semiconductor device according to clause 60 or 61, in which the well region (54) includes a portion extending out of the peripheral region (18) into the IGBT region (14) and covering a bottom wall of the trench gate structure (38).

### Clause 63

The semiconductor device according to any one of clauses 13 to 62, in which the inner cathode region (120) has a loop shape surrounding the IGBT region (14).

### Clause 64

The semiconductor device according to clause 21, in which the cathode extension (134) extends farther toward the peripheral edge of the chip (12) than the well region (54).

### Clause 65

The semiconductor device according to clause 64, in which the cathode extension (134) extends to a position facing the field region (56) in the thickness direction (Z) of the chip (12).

### Clause 66

The semiconductor device according to clause 8, in which the cathode region (110) faces the field regions (56) in the thickness direction (Z) of the chip (12) along an entire perimeter of the field regions (56).

The above descriptions are merely exemplary. One skilled in the art would recognize the potential for a wide variety of combinations and substitutions of the elements and methods (manufacturing processes) in addition to those illustrated to describe the techniques of this disclosure. Any substitutions, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a chip including a first main surface and a second main surface opposite of the first main surface;
a peripheral region located in a peripheral edge portion of the first main surface;
an IGBT region located at an inner side of the peripheral region of the first main surface;
a well region of a first conductivity type formed in a surface region of the first main surface in the peripheral region to define the IGBT region;
field regions of the first conductivity type formed in the surface region of the first main surface in the peripheral region and separated from the well region toward a peripheral edge of the chip, the field regions being spaced apart from each other;
a cathode region of a second conductivity type formed in a surface region of the second main surface in the peripheral region, the cathode region forming a diode together with the well region;
an insulating film covering at least the well region;
an emitter electrode formed on the insulating film to be electrically connected to the well region; and
a collector electrode formed on the second main surface to be electrically connected to the cathode region,
wherein the cathode region is located closer to the peripheral edge of the chip than the well region is, and the cathode region is formed to face at least one of the field regions in a thickness direction of the chip.

2. The semiconductor device according to claim 1, wherein
the field regions include an outermost field region located closest to the peripheral edge of the chip,
the field regions include an inner field region located closer to the well region than the outermost field region is, and
the cathode region is formed to face the inner field region in the thickness direction of the chip.

3. The semiconductor device according to claim 1, wherein the cathode region is formed to face one of the field regions located relatively close to the well region in the thickness direction of the chip.

4. The semiconductor device according to claim 1, wherein a width of the cathode region is equal to a width of one of the field regions.

5. The semiconductor device according to claim 1, wherein a width of the cathode region is greater than a width of one of the field regions and less than two times the width of the one of the field regions.

6. The semiconductor device according to claim 1, wherein the cathode region extends so as to face the field regions in the thickness direction of the chip.

7. The semiconductor device according to claim 1, further comprising a channel stop region formed in the surface region of the first main surface in the peripheral region and separated from the field regions toward the peripheral edge of the chip,
wherein the cathode region is formed to face a position separated from the channel stop region toward the field regions in the thickness direction of the chip.

8. The semiconductor device according to claim 1, wherein, as viewed in the thickness direction of the chip, the cathode region has a loop shape surrounding the well region.

9. The semiconductor device according to claim 1, further comprising a collector region of the first conductivity type formed in a surface region of the second main surface,
wherein the cathode region has a second conductivity type impurity concentration that is higher than a first conductivity type impurity concentration of the collector region.

10. The semiconductor device according to claim 1, wherein
the field regions include a specific field region in which an electric field having a maximum intensity occurs when a collector-emitter voltage is applied, and
the cathode region is formed to face the specific field region in the thickness direction of the chip.

11. The semiconductor device according to claim 2, further comprising:
an inner field electrode formed on the insulating film and electrically connected to the inner field region; and
an outermost field electrode formed on the insulating film and electrically connected to the outermost field region,
wherein a width of the outermost field electrode is greater than a width of the inner field electrode.

12. The semiconductor device according to claim 2, wherein a width of the inner field region is less than a width of the outermost field region.

13. The semiconductor device according to claim 1, further comprising:
a well connection electrode embedded in the insulating film to be connected to the well region;
a gate line electrode formed on the insulating film and separated from the well connection electrode so as to face the well region; and
an inner cathode region of the second conductivity type formed in the surface region of the second main surface, the inner cathode region being separated from a gate reference position toward the well connection electrode along the second main surface so as to face the well region, the gate reference position being directly below a center of the gate line electrode, the inner cathode region forming a diode together with the well region.

14. The semiconductor device according to claim 13, wherein a distance between the center of the gate line electrode and the well connection electrode is a reference distance, and the inner cathode region is absent within a range not exceeding one-half of the reference distance from the gate reference position toward the well connection electrode.

15. The semiconductor device according to claim 13, wherein a distance between the center of the gate line electrode and the well connection electrode is a reference distance, and the inner cathode region includes a portion located in a range not exceeding one-half of the reference distance from a well reference position located directly below the well connection electrode.

16. The semiconductor device according to claim 15, wherein the inner cathode region is absent within a range not exceeding one-half of the reference distance from the gate reference position toward the well connection electrode.

17. The semiconductor device according to claim 13, wherein the inner cathode region includes a portion facing the well connection electrode in the thickness direction of the chip.

18. The semiconductor device according to claim 13, wherein the inner cathode region does not face the gate line electrode in the thickness direction of the chip.

19. The semiconductor device according to claim 13, wherein
the gate line electrode is separated from the well connection electrode toward the IGBT region, and
the inner cathode region is separated from the gate reference position toward the well connection electrode along the second main surface.

20. The semiconductor device according to claim 19, wherein the inner cathode region is formed in the surface region of the second main surface only in a region facing the well region.
